(19) United States
(12) Patent Application Publication
(10) Pub. No.: US 2026/0333855 A1
(43) Pub. Date: Oct. 22, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 19/182,986

(22) Filed: Apr. 18, 2025

(51) Int. Cl. H10D 84/85; H10D 30/00; H10D 30/01; H10D 30/43; H10D 62/10; H10D 62/13; H10D 64/01; H10D 64/23; H10D 84/01

(52) U.S. Cl. CPC H10D 84/851; H10D 30/014; H10D 30/0194; H10D 30/43; H10D 30/503; H10D 30/506; H10D 62/121; H10D 62/151; H10D 64/017; H10D 64/256; H10D 84/017; H10D 84/0186; H10D 84/856

(57) ABSTRACT

A semiconductor structure is provided. The semiconductor structure includes a plurality of nanostructures which include a first nanostructure, a second nanostructure, and a third nanostructure sequentially stacked upwardly. The third nanostructure is thicker than the second nanostructure and the first nanostructure. The semiconductor structure further includes a gate stack, a source/drain feature, a dielectric layer, and a contact structure. The gate stack extends lengthwise along a first direction. The gate stack is wrapped around the center portions of the nanostructures. The source/drain feature interfaces with the end portions of the nanostructures. The dielectric layer is over the source/drain feature. The contact structure passes through the dielectric layer and the source/drain feature. The thickness of the source/drain feature is different from the width of the source/drain feature in a cross-sectional view. The bottom surface of the contact structure is lower than the top surface of the second nanostructure.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1, 3B-1, 3C-1, 3D-1, 3E-1, 3F-1, 3G-1, 3H-1, 3I-1, 3J-1 and 3K-1 are cross-sectional views illustrating the formation of a semiconductor structure at various intermediate stages corresponding to line Y1-Y1 of FIG. 2, in accordance with some embodiments of the disclosure.

FIGS. 3A-2, 3B-2, 3C-2, 3D-2, 3E-2, 3F-2, 3G-2, 3H-2, 3I-2, 3J-2 and 3K-2 are cross-sectional views illustrating the formation of a semiconductor structure at various intermediate stages corresponding to line Y2-Y2 of FIG. 2, in accordance with some embodiments of the disclosure.

FIGS. 3A-3, 3B-3, 3C-3, 3D-3, 3E-3, 3F-3, 3G-3, 3H-3, 3I-3, 3J-3 and 3K-3 are cross-sectional views illustrating the formation of a semiconductor structure at various intermediate stages corresponding to line X1-X1 of FIG. 2, in accordance with some embodiments of the disclosure.

FIGS. 3G-4, 3H-4, 3I-4, 3J-4 and 3K-4 are cross-sectional views illustrating the formation of a semiconductor structure at various intermediate stages corresponding to line Y3-Y3 of FIG. 2, in accordance with some embodiments of the disclosure.

FIGS. 3G-5, 3H-5, 3I-5, 3J-5 and 3K-5 are cross-sectional views illustrating the formation of a semiconductor structure at various intermediate stages corresponding to line X2-X2 of FIG. 2, in accordance with some embodiments of the disclosure.

FIG. 3F-4 is a plan view illustrating the semiconductor structure of FIG. 3F-1 taken along plane A-A, in accordance with some embodiments of the disclosure.

FIG. 3J-6 is a plan view illustrating the semiconductor structure of FIG. 3J-1 taken along plane A-A, in accordance with some embodiments of the disclosure.

FIG. 3J-7 is an enlarged view of FIG. 3J-5, in accordance with some embodiments of the disclosure.

FIG. 4 is a modification of the semiconductor structure of FIG. 3K-3, in accordance with some embodiments of the disclosure.

FIG. 5 is a modification of the semiconductor structure of FIG. 3K-2, in accordance with some embodiments of the disclosure.

FIG. 6 is a modification of the semiconductor structure of FIG. 3K-2, in accordance with some embodiments of the disclosure.

FIGS. 7-1 and 7-2 is a modification of the semiconductor structure of FIG. 3K-2 and 3K-4, in accordance with some embodiments of the disclosure.

FIG. 8A illustrates a modification of the semiconductor structure of FIG. 3K-2, in accordance with some embodiments of the disclosure.

FIG. 8B illustrates a modification of the semiconductor structure of FIG. 3K-2, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The aspect of the present disclosure is directed to a semiconductor structure including nanostructure transistors. The semiconductor structure includes nanostructures surrounded by a gate stack and source/drain features interfaced with the nanostructures. The top nanostructure is the thickest among all nanostructures, which may alleviate the current crowding issue. Furthermore, each of the nanostructures includes a thicker end portion and a thinner center portion. The thicker end portion may reduce the resistance, and the thinner center portion may help enhance the gate control over the channel. Therefore, the performance and/or the reliability of the resulting semiconductor device may improve.

In addition, the semiconductor structure further includes a contact structure extending into the source/drain feature. The contact opening is formed using two separate etching processes. As a result, the contact structure may extend to a deep position while preventing the contact structure from coming into contact with the channels and/or the inner spacer layers. Therefore, the performance and/or the reliability of the resulting semiconductor device may be enhanced. Furthermore, the top surface of the gate electrode layer is level with the top surface of the contact structure, which may reduce the parasitic capacitance. The performance of the resulting semiconductor device may be further improved.

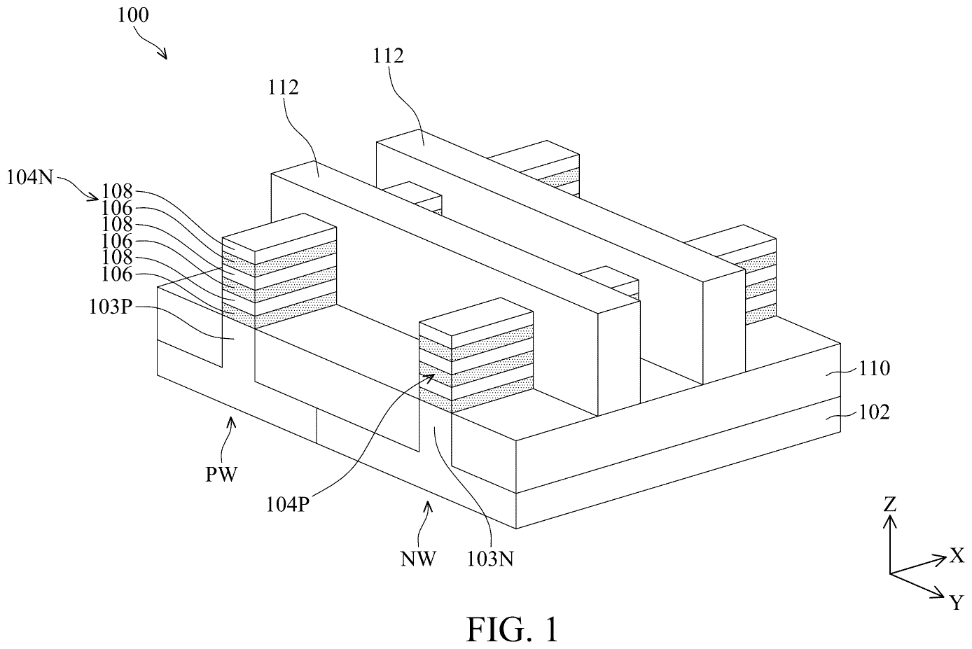

FIG. 1 is a perspective view of a semiconductor structure 100, in accordance with some embodiments. The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW, and the fin structure 104P is formed in the n-type well NW, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments.

Each of the fin structures 104N and 104P further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

The fin structures 104N and 104P extend in the X direction, in accordance with some embodiments. That is, the fin structures 104N and 104P have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are arranged in an alternating manner, in accordance with some embodiments. In this disclosure, a source/drain refers to a source and/or a drain. It should be noted that source/drain region(s) may refer to a source or a drain, individually or collectively dependent upon the context.”

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-extending direction.

Although two fin structures 104 and two gate structures 112 are illustrated in FIG. 1, the semiconductor structure 100 is not intended to be limiting. The number of fin structures and the gate structures may be dependent on the design demand of an integrated circuit and/or performance consideration of resulting semiconductor devices.

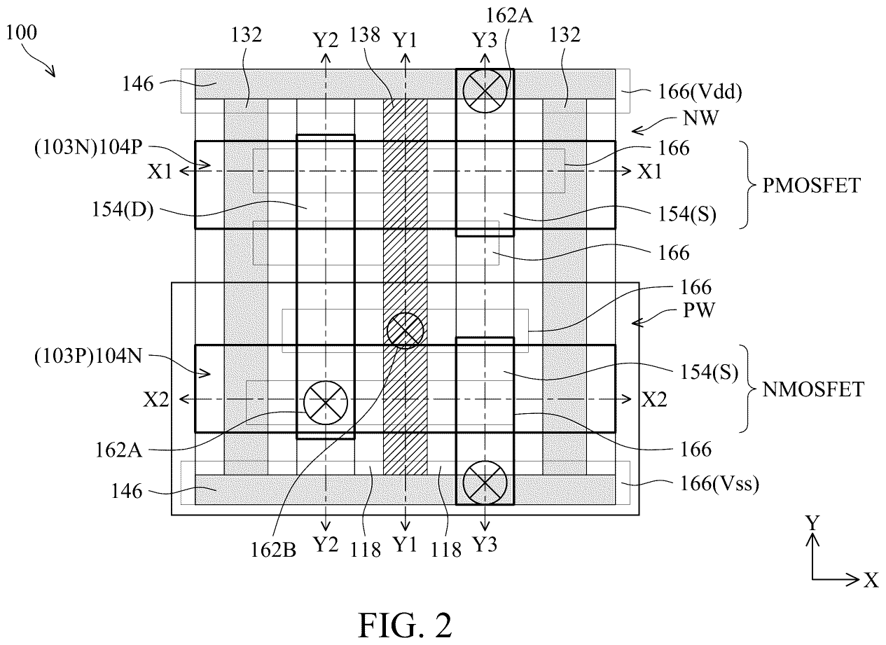

FIG. 2 is a layout (or a plan view) of a semiconductor structure 100, in accordance with some embodiments.

The semiconductor structure 100 may be or include nanostructure devices (e.g., GAA FETs), in accordance with some embodiments. The semiconductor structure 100 includes active regions 104 (including 104N and 104P) over a substrate (as shown in FIG. 1), and a final gate stack 138 across the active regions 104, in accordance with some embodiments. The substrate includes a p-type well PW and an n-type well NW, in accordance with some embodiments. The p-type well PW and the n-type well NW are immediately arranged in the Y direction, in accordance with some embodiments. The active region 104N is located on the p-type well PW, and the active region 104P is located on the n-type well NW, in accordance with some embodiments.

Each of the active regions 104 includes a lower fin element 103N (or 103P) and nanostructures (not shown in FIG. 2) formed over the lower element 103N (or 103P), in accordance with some embodiments. The final gate stack 138 extends in the Y direction across the channel regions of the active regions 104N and 104P, in accordance with some embodiments. The final gate stack 138 wraps around the nanostructures of the active regions 104N and 104P. Gate spacer layers 118 are formed along the opposite sides of the final gate stack 138, in accordance with some embodiments.

The final gate stack 138 is combined with the nanostructures of the active regions 104N and 104P to form nanostructure transistors, in accordance with some embodiments. The nanostructure transistors are formed at the cross points between the active regions 104 and the final gate stack 138, in accordance with some embodiments. For example, the nanostructure transistors formed in the p-type well PW are n-channel nanostructure transistors NMOSFET, and the nanostructure transistors formed in the n-type well NW are p-channel nanostructure transistors PMOSFET.

Fin-cut structures 132 extend in the Y direction and cut through active regions 104N and 104P, in accordance with some embodiments. In some embodiments, the fin-cut structures 132 are formed by replacing dummy gate structures with dielectric material. Gate spacer layers 118 are also formed along the opposite sides of the fin-cut structures 132, in accordance with some embodiments.

Gate-cut structures 146 extend in the X direction and cut through the final gate stack 138 and the gate spacer layers 118, in accordance with some embodiments. The gate-cut structures 146 and the fin-cut structures 132 may be configured to collectively define a cell region in which a functional circuit is formed (e.g., inverter circuit, NAND circuit, NOR circuit, etc.). For example, the gate-cut structures 146 are located on the opposite boundaries of a cell region with respect to the Y direction, and the fin-cut structures 132 may be located on the opposite boundaries of the cell region with respect to the X direction, in accordance with some embodiments. In some embodiments, the cell region is an inverter cell.

Contact structures 154 (including 154(S) and 154(D)) are formed over the source/drain regions of the active regions 104N and 104P, in accordance with some embodiments. Contact structures 154 extends in the Y direction across the source/drain regions of the active regions 104N and 104P. In some embodiments, two 154(S) of the contact structures are electrically connected to the source terminals of the nanostructure transistors PMOSFET and NMOSFET, respectively. In some embodiments, one 154(D) of the contact structures is electrically connected to the drain terminals of both the nanostructure transistors PMOSFET and NMOSFET.

A first-level metal layer (M1) is formed over the contact structures 154, in accordance with some embodiments. The first-level metal layer includes several metal lines (tracks) 166, e.g., power supply lines and signal lines, in accordance with some embodiments. The power supply lines 166 include a Vdd power rail providing positive voltage and a Vss power rail which may be an electrical ground, in accordance with some embodiments.

The Vss power rail 166 is electrically connected to the Vss node (e.g., source terminals) of the n-channel nanostructure transistors NMOSFET through vias 162A, in accordance with some embodiments. The Vdd power rail 166 is electrically connected to the Vdd node (e.g., source terminals) of the p-channel nanostructure transistors PMOSFET through vias 162A, in accordance with some embodiments. The signal lines 166 are configured for signal transmission and are electrically drain terminals and gate terminals of the nanostructure transistors through vias 162A and 162B, in accordance with some embodiments. In some embodiments, the dimension of the vias 162B in the X direction is greater than the dimension of the vias 162A in the X direction, and the dimension of the vias 162B in the Y direction is greater than the dimension of the vias 162A in the Y direction. In some embodiments, the vias 162B which are connected between the contact structures 154(S) and the power rails 166 overlap the gate-cut structures 146. In some embodiments, the via 162B which is connected between the contact structure 154(D) and the signal line 166 overlaps the active region 104N.

The metal lines 166 of the first-level metal layer extend in the X direction, in accordance with some embodiments. The Vdd and Vss power rails 166 extend along the boundaries of the cell region and overlap the gate-cut structures 146, in accordance with some embodiments.

FIG. 2 further illustrates reference cross-sections that are used in later figures. Cross-sections X1-X1 and X2-X2 are in planes parallel to the longitudinal axis (X direction) of the active regions 104 and respectively through the active regions 104P and 104N. Cross-section Y1-Y1 is in a plane parallel to the longitudinal axis (Y direction) of t he final gate stack 138 and through the final gate stack 138 (or a dummy gate structure). Cross-section Y2-Y2 is in a plane parallel to the longitudinal axis (Y direction) of the final gate stack 138 and across the source/drain regions of the active regions 104N and 104P for the drain terminal. Cross-section Y3-Y3 is in a plane parallel to the longitudinal axis (Y direction) of the final gate stack 138 and across the source/drain regions of the active regions 104N and 104P for the source terminal.

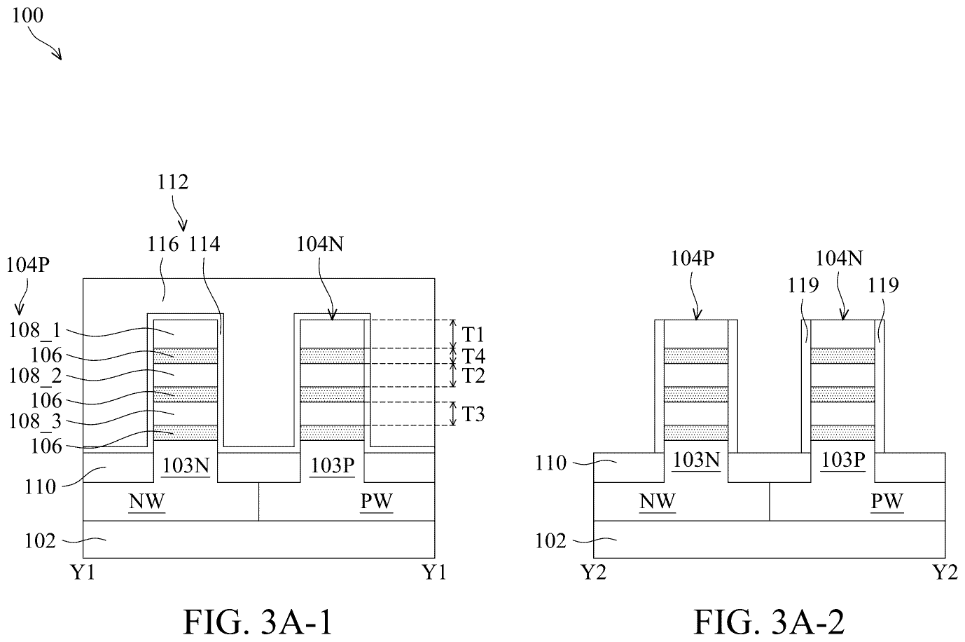

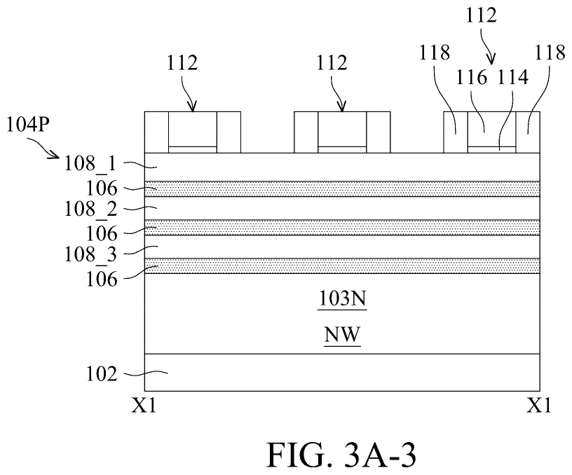

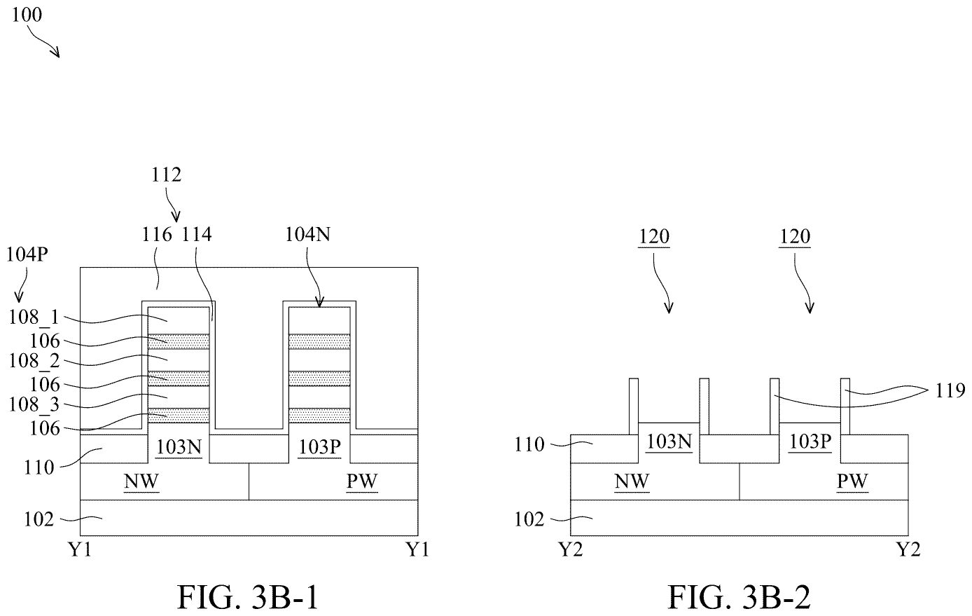

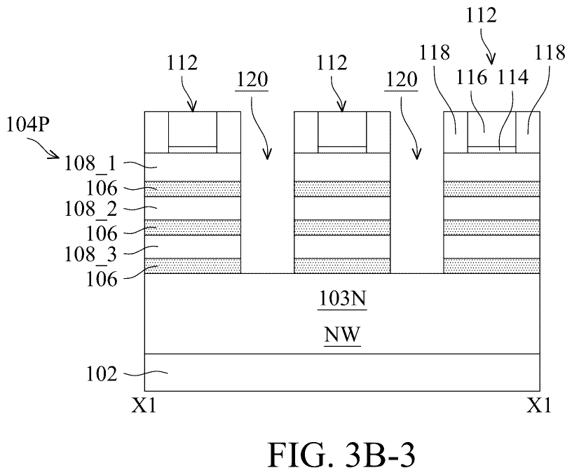

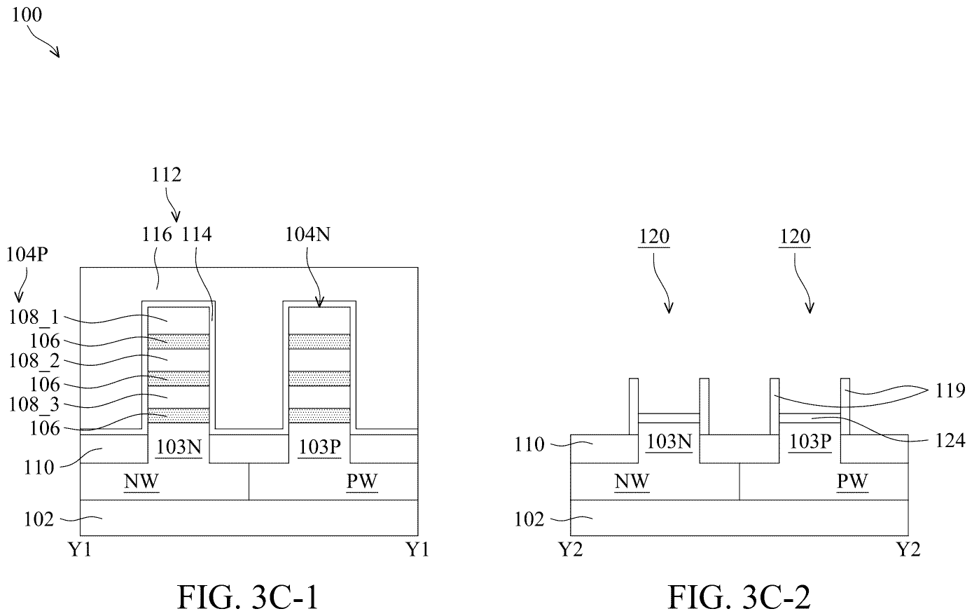

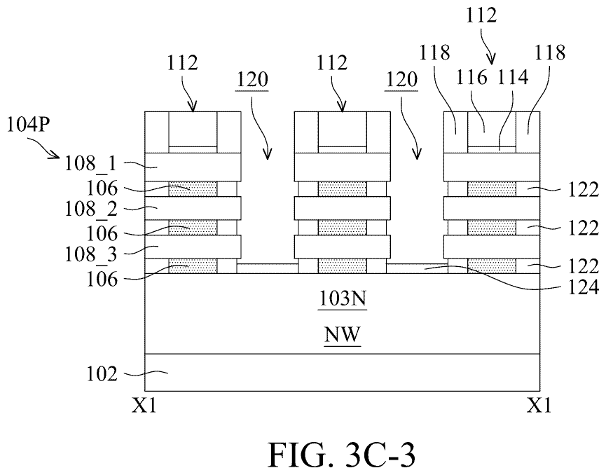

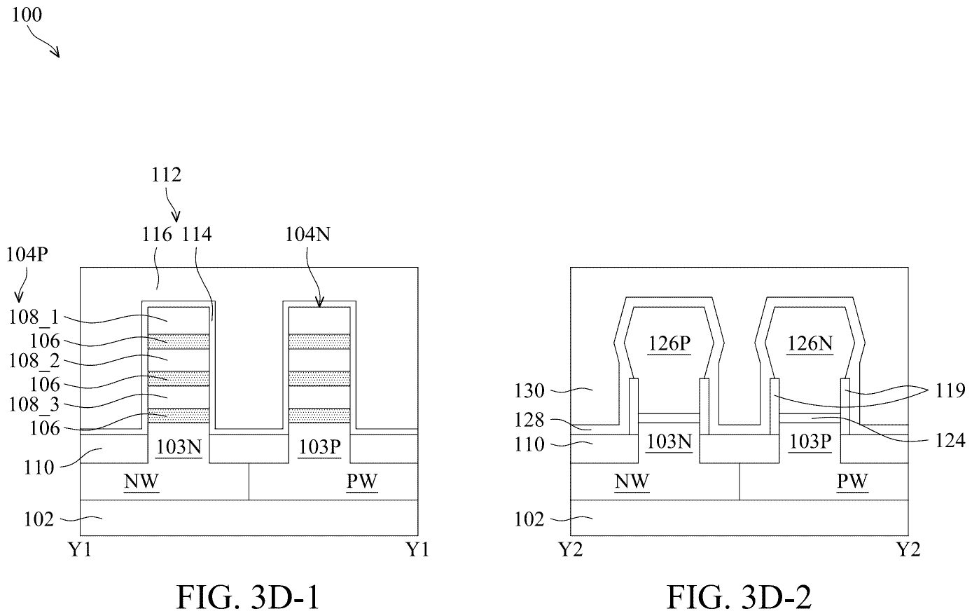

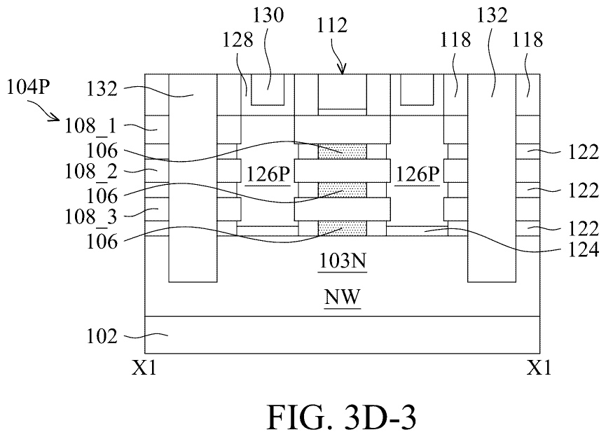

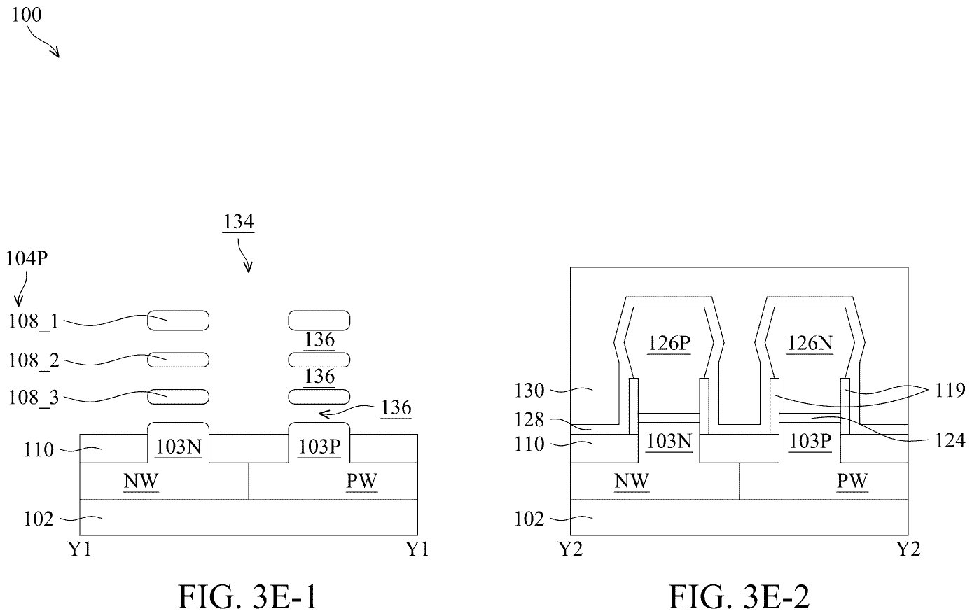

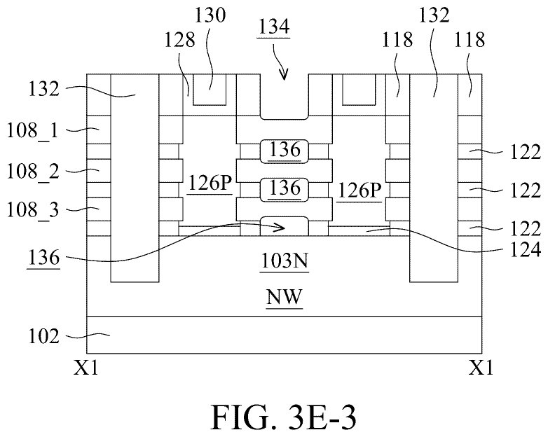

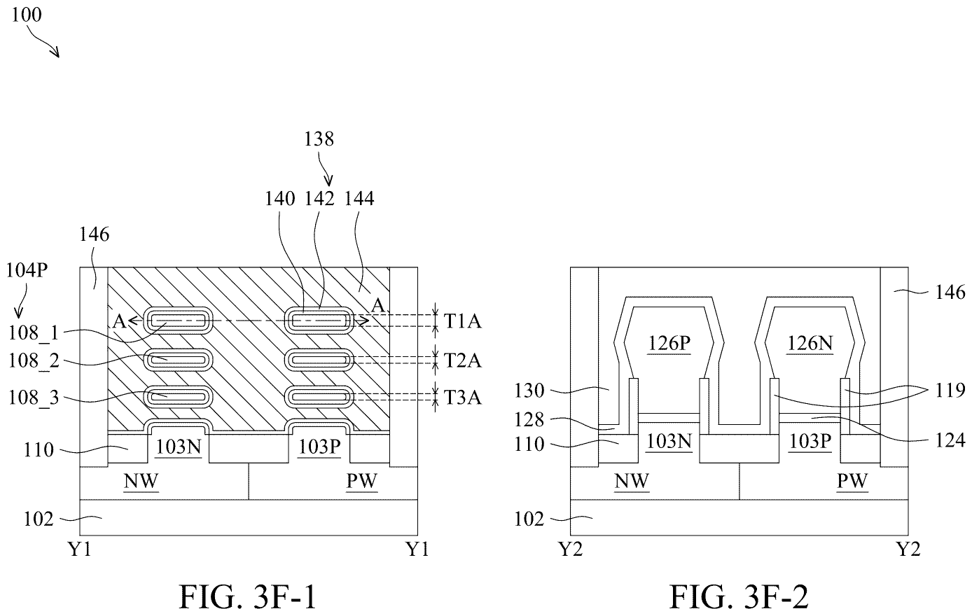

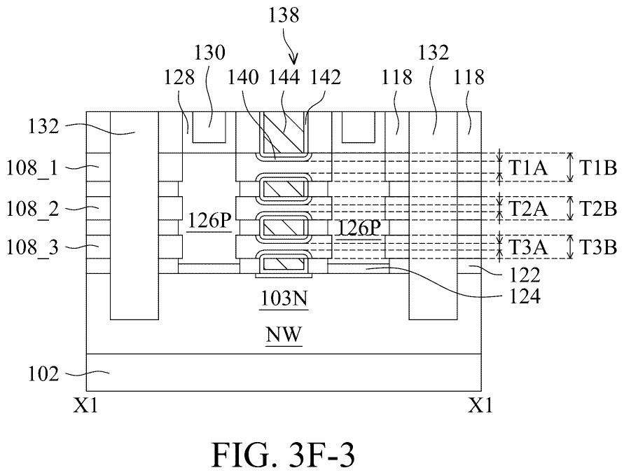

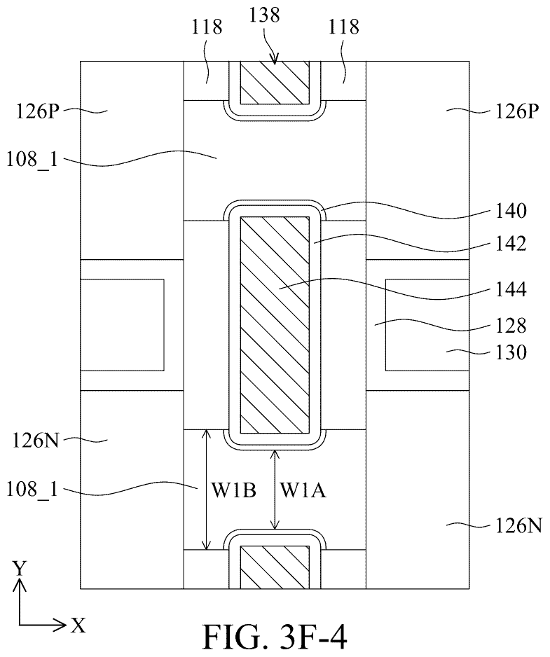

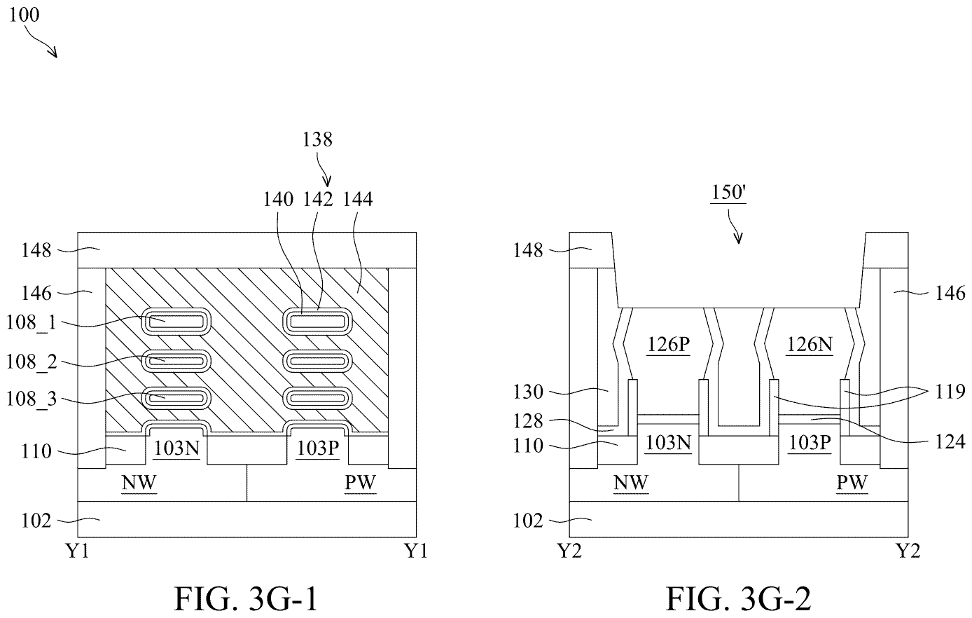

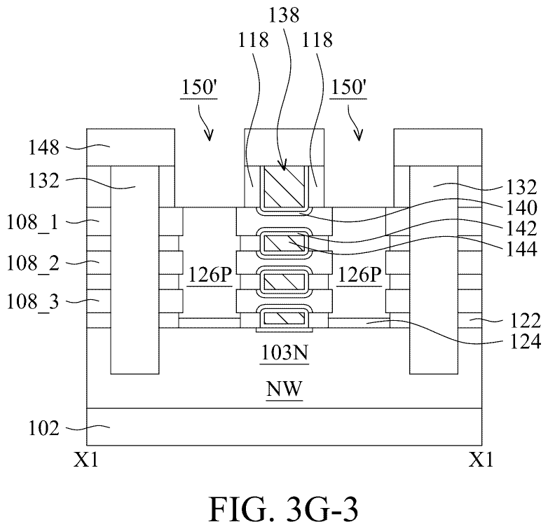

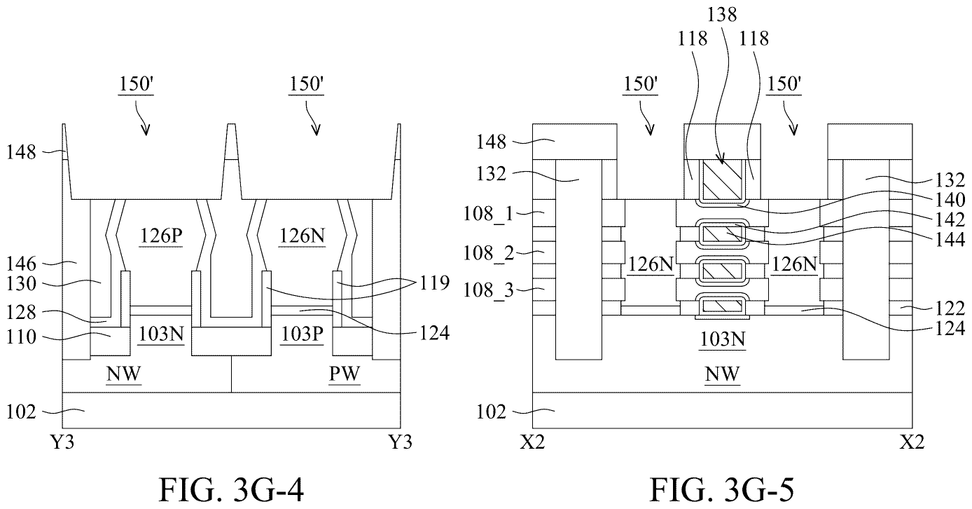

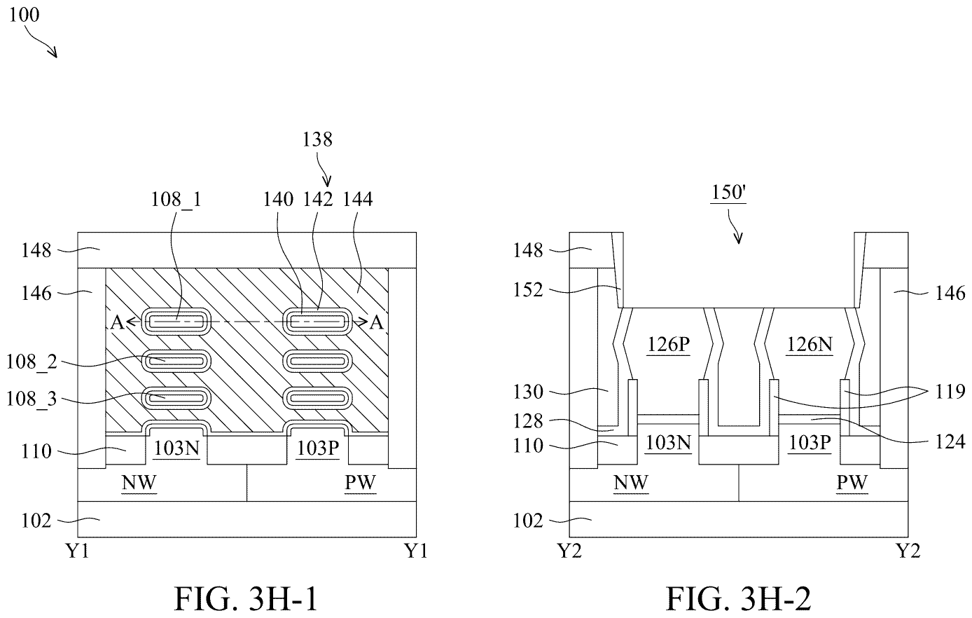

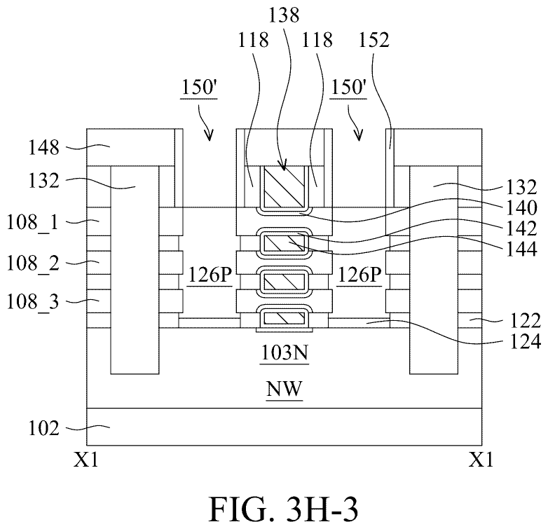

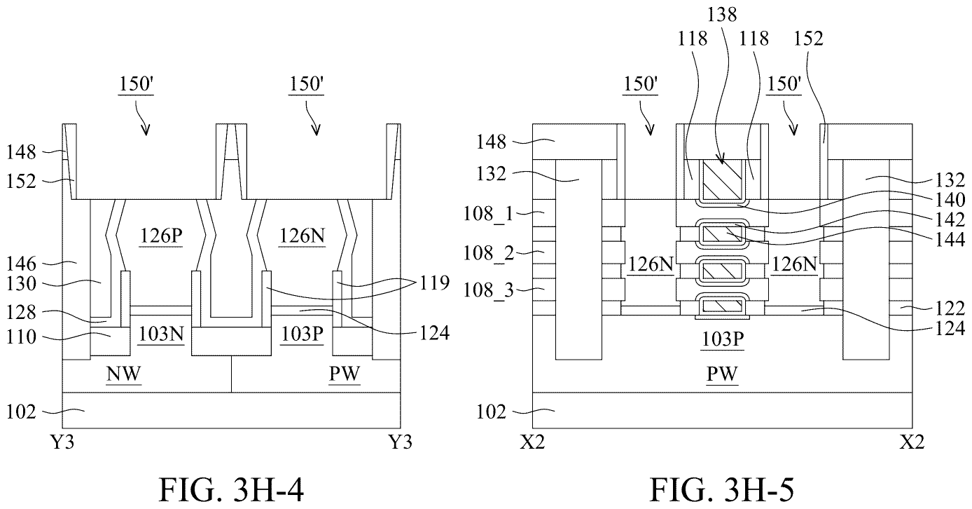

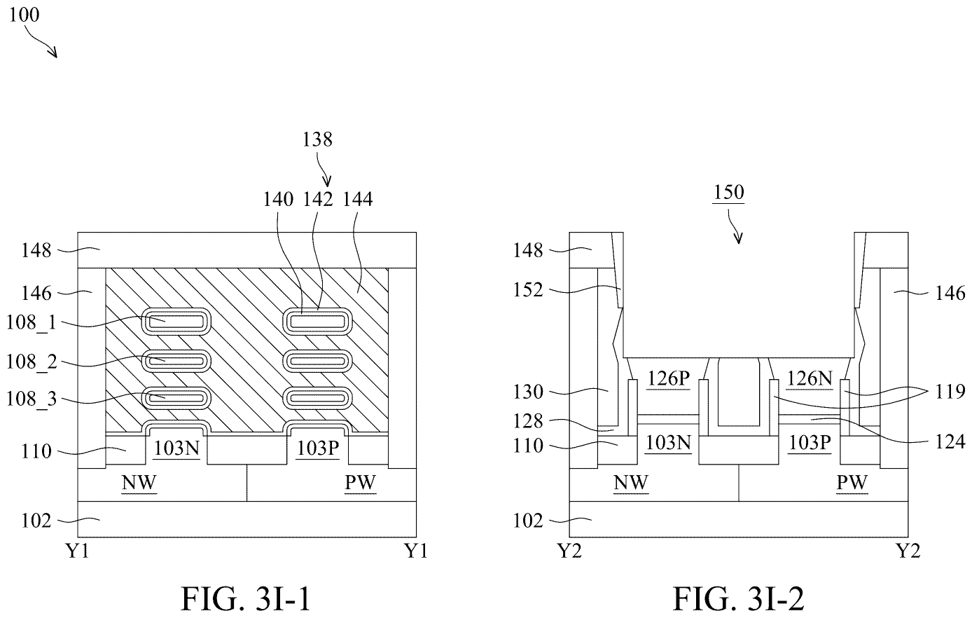

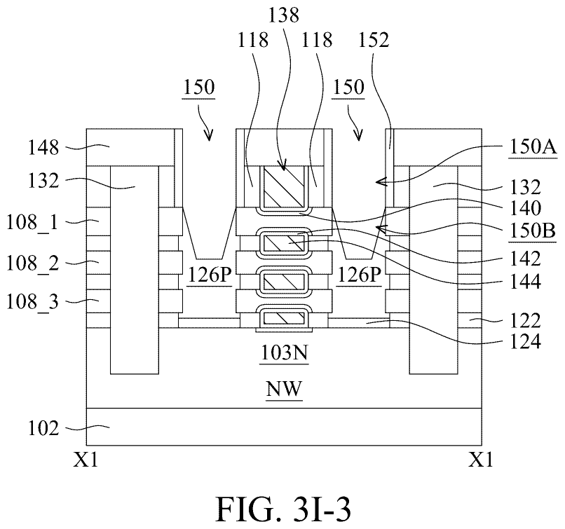

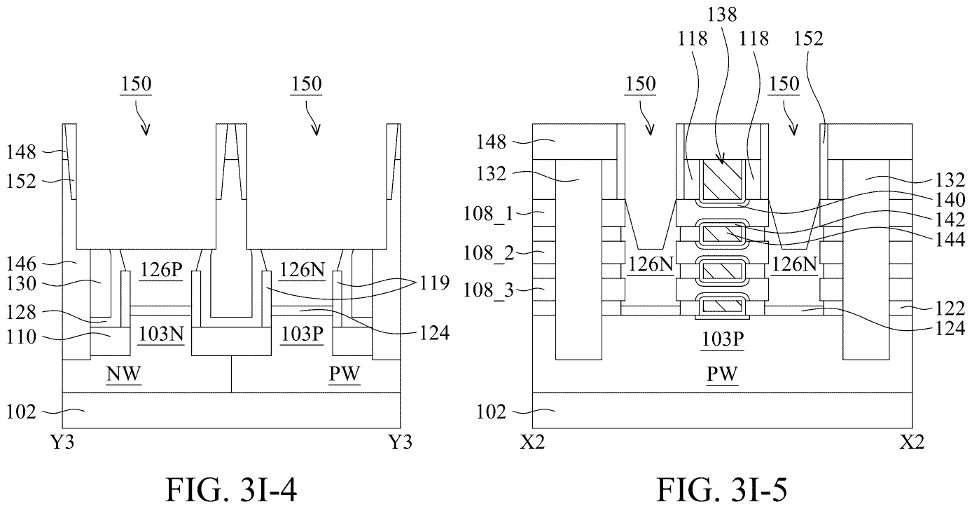

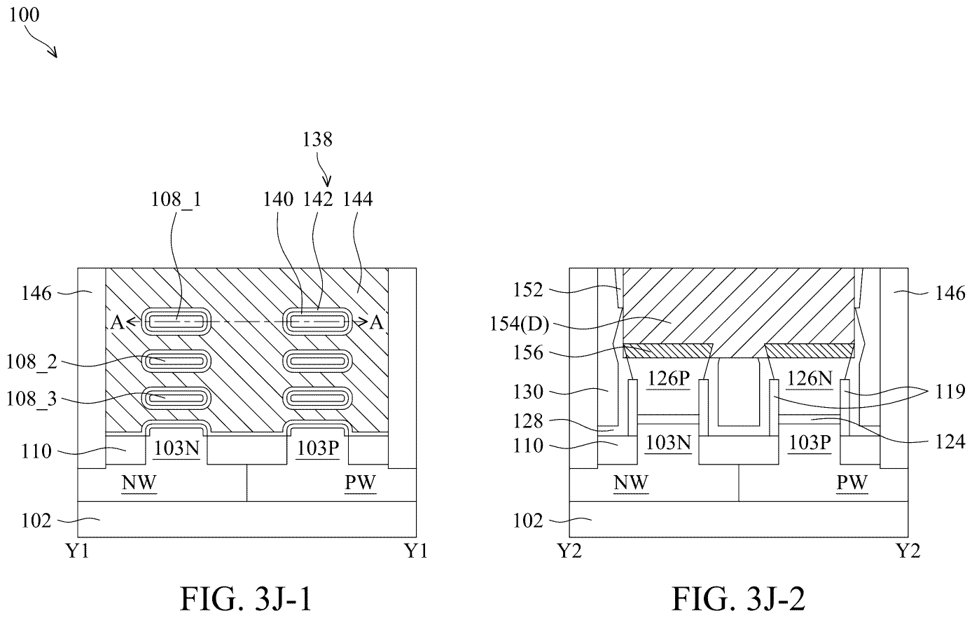

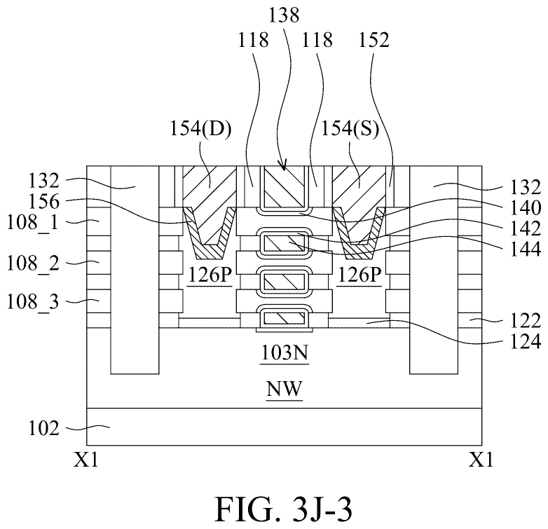

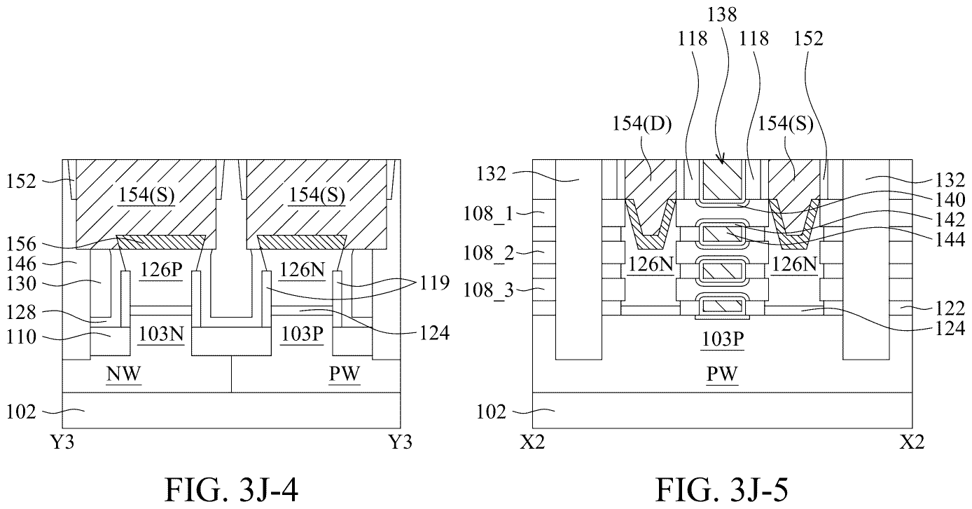

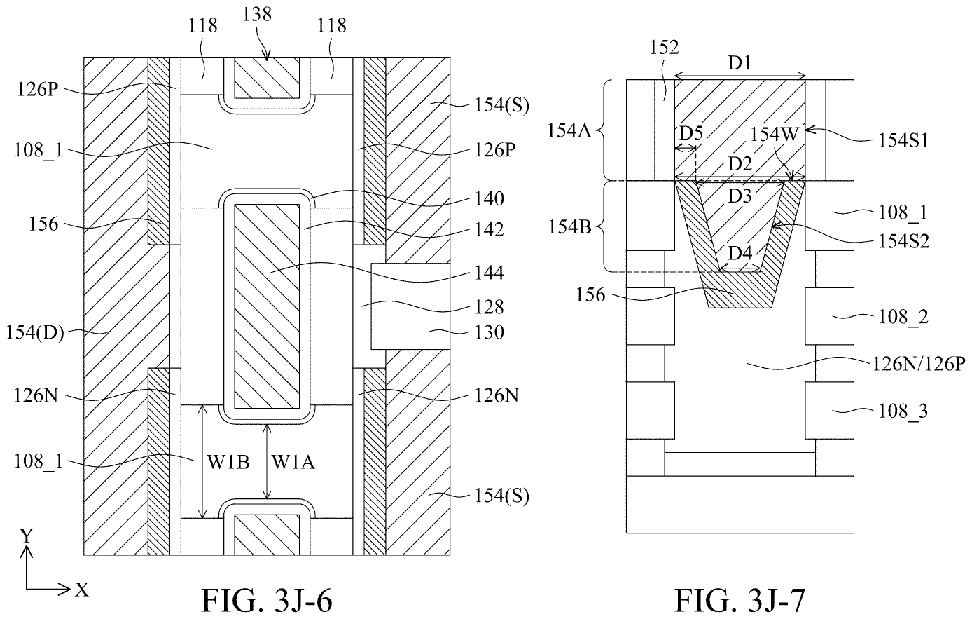

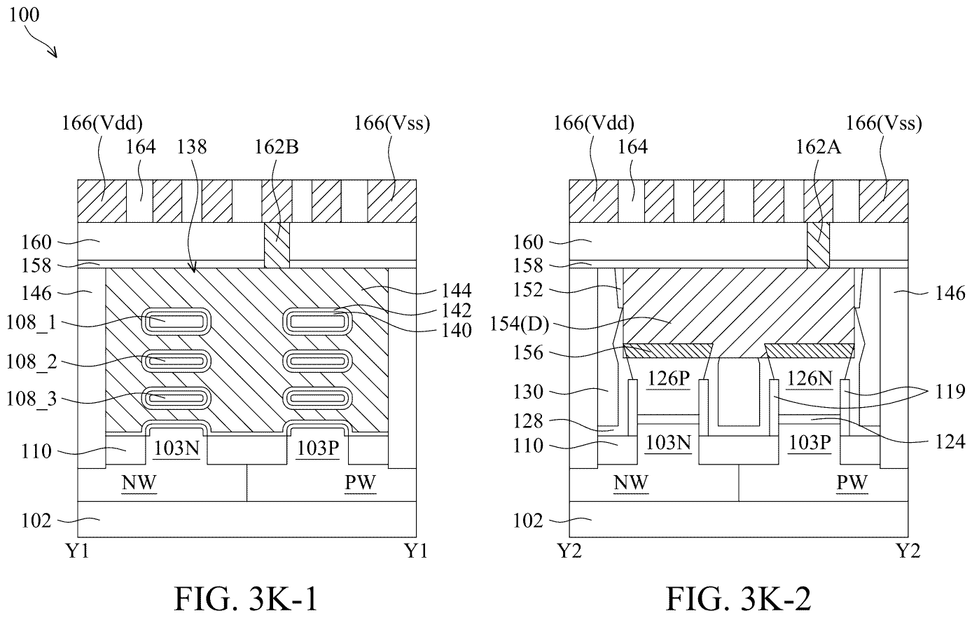

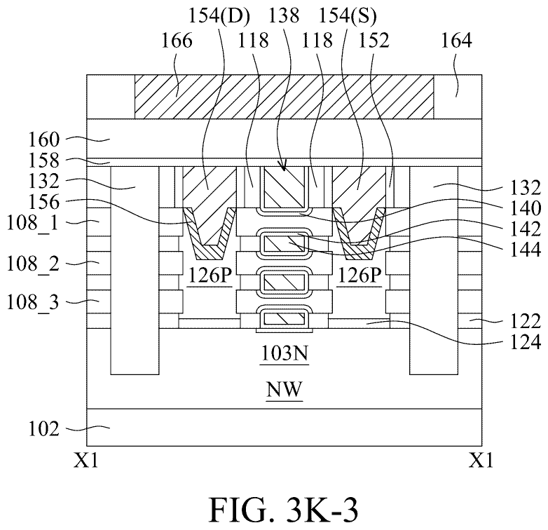

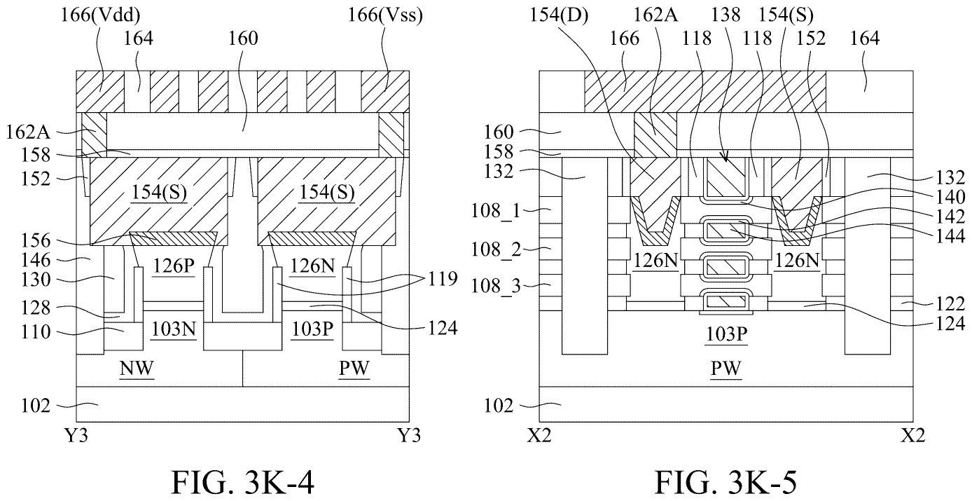

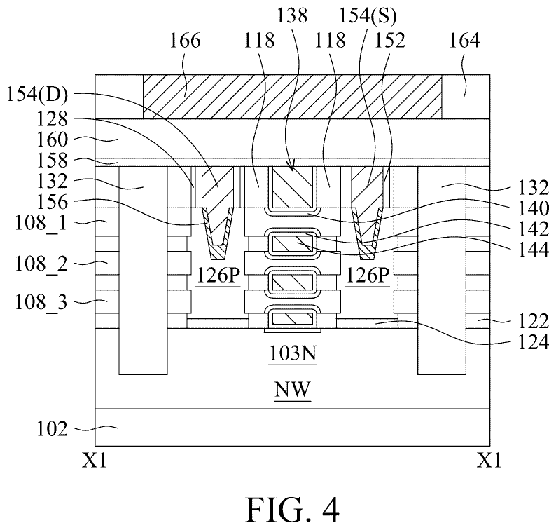

FIGS. 3A through 3K-5 are cross-sectional views illustrating the formation of a semiconductor structure 100 at various intermediate stages, in accordance with some embodiments of the disclosure. FIGS. 3A-1, 3B-1, 3C-1, 3D-1, 3E-1, 3F-1, 3G-1, 3H-1, 3I-1, 3J-1 and 3K-1 correspond to line Y2-Y2 of FIG. 2. FIGS. 3A-2, 3B-2, 3C-2, 3D-2, 3E-2, 3F-2, 3G-2, 3H-2, 3I-2, 3J-2 and 3K-2 correspond to line Y2-Y2 of FIG. 2. FIGS. 3A-3, 3B-3, 3C-3, 3D-3, 3E-3, 3F-3, 3G-3, 3H-3, 3I-3, 3J-3 and 3K-3 correspond to line X1-X1 of FIG. 2. FIGS. 3G-4, 3H-4, 3I-4, 3J-4 and 3K-4 correspond to line Y3-Y3 of FIG. 2. FIGS. 3G-5, 3H-5, 3I-5, 3J-5 and 3K-5 correspond to line X2-X2 of FIG. 2.

FIGS. 3A-1 to 3A-3 illustrate a semiconductor structure 100 after the formation of active regions 104N and 104P, an isolation structure 110, dummy gate structures 112, gate spacer layers 118 and fin spacer layers 119, in accordance with some embodiments.

A substrate 102 is provided, as shown in FIGS. 3A-1 to 3A-3, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

An n-type well NW and a p-type well PW are formed in the substrate 102, in accordance with some embodiments. In some embodiments, the n-type well NW and the p-type well PW have different electrically conductive types. In some embodiments, the wells NW and PW are formed by respective ion implantation processes. In some embodiments, the ion implantation processes may be performed several times with different dosages and different energy intensities. In some embodiments, the ion implantation process may include anti-punch through (APT) implant.

Active regions 104 (including 104N and 104P) are formed over the substrate 102 as shown in FIGS. 3A-1 to 3A-3, in accordance with some embodiments. In some embodiments, the active regions 104N and 104P extend in the X direction. In some embodiments, the active regions 104N and 104P are the fin structures 104N and 104P as shown in FIG. 1.

The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N and 104P further includes patterning the epitaxial stack and underlying wells PW and NW using photolithography and etching processes, thereby forming trenches, in accordance with some embodiments. The active regions 104N and 104P protrude from between trenches, in accordance with some embodiments.

The p-type well PW protruding from between the trenches forms the lower fin element 103P of the active region 104N, and the n-type well NW protruding from between the trenches forms the lower fin element 103N of the active region 104P, in accordance with some embodiments. The remainder of the epitaxial stack (including the semiconductor layers 106 and 108) forms the upper fin elements of the active regions 104N and 104P, in accordance with some embodiments.

In some embodiments, the second semiconductor layers 108 includes a bottom (or bottommost) second semiconductor layers 108_3, a middle second semiconductor layers 108_2, and top (or topmost) second semiconductor layers 108_1 that are sequentially stacked upwardly, as shown in FIGS. 3A-1 to 3A-3. In some embodiments, the top second semiconductor layers 108_1 has a thickness T1 in a range from about 7 nm to about 23 nm, the middle second semiconductor layers 108_2 has a thickness T2 in a range from about 7 nm to about 23 nm, and the bottom second semiconductor layers 108_3 has a thickness T3 in a range from about 7 nm to about 23 nm.

In some embodiments, the top second semiconductor layer 108_1 is the thickest layer among the plurality of second semiconductor layers 108. That is, the thickness T1 of the top second semiconductor layers 108_1 is greater than the thickness T2 of the middle second semiconductor layers 108_2 and the thickness T3 of the bottom second semiconductor layers 108_3. In some embodiments, the thickness T2 may be less than, equal to or greater than the thickness T3.

In some embodiments, the ratio (T1/T2) of the thickness T1 to thickness T2 is in a range from about 1.05 to about 1.3. In some embodiments, the ratio (T1/T3) of the thickness T1 to thickness T3 is in a range from about 1.05 to about 1.3.

In some embodiments, each of the first semiconductor layers 106 has a thickness T4 in a range from about 4 nm to about 15 nm. In some embodiments, the pitch of the second semiconductor layers 108 is in a range from about 7 nm to about 23 nm. The thickness of the second semiconductor layers 108 may be greater than, equal to, or less than the first semiconductor layers 106, depending on the amount of gate materials to be filled in spaces where the first semiconductor layers 106 are removed. Although three first semiconductor layers 106 and three second semiconductor layers 108 are shown, the number is not limited to three, and can be two or four, and is less than 10.

An isolation structure 110 is formed to surround the lower fin elements 103N and 103P, as shown in FIGS. 3A-1 and 3A-2, in accordance with some embodiments. The isolation structure 110 is configured to electrically isolate active regions 104 from one another, and is also referred to as shallow trench isolation (STI) feature, in accordance with some embodiments. In some embodiments, the isolation structure 110 has a substantially flat top surface. In some other embodiments, the isolation structure 110 has a curved top surface.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process (e.g., chemical mechanical polishing (CMP), etching back process, or a combination thereof) is performed on the insulating material, in accordance with some embodiments. The insulating material is then recessed by an etching process (such as dry plasma etching and/or wet chemical etching) until the upper fin elements of the active regions 104 are exposed, in accordance with some embodiments. The top portions of the lower fin element 103N and 104P may be further exposed from the isolation structure 110, in accordance with some embodiments.

Dummy gate structures 112 are formed across the active regions 104N and 104P and the isolation structure 110, as shown in FIGS. 3A-1 and 3A-3, in accordance with some embodiments. The dummy gate structures 112 are configured as sacrificial structures and will be replaced with the final gate stacks, in accordance with some embodiments. In some embodiments, the dummy gate structures 112 extend in the Y direction. The dummy gate structures 112 surround the channel regions of the active regions 104N and 104P, in accordance with some embodiments. The dummy gate structures 112 are the gate structures 112 shown in FIG. 1.

Each of the dummy gate structures 112 includes a dummy gate dielectric layer 114 and a dummy gate electrode layer 116 over the dummy gate dielectric layer, in accordance with some embodiments. In some embodiments, the dummy gate dielectric layer 114 is conformally formed along the upper fin elements of the active regions 104 using ALD, CVD, thermal oxidation, physical vapor deposition (PVD), another suitable technique, or a combination thereof. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112 using photolithography and etching processes.

Gate spacer layers 118 are formed along opposite sidewalls of the dummy gate structures 112, and fin spacer layers 119 are formed along opposite sidewalls of the active regions 104N and 104P, as shown in FIGS. 3A-2 and 3A-3, in accordance with some embodiments. The gate spacer layers 118 extend in the Y direction and across the active regions 104N and 104P and the isolation structure 110, in accordance with some embodiments. The gate spacer layers 118 are used to offset the subsequently formed source/drain features and separate the source/drain features from the gate structure, in accordance with some embodiments. The fin spacer layers 119 extend in the X direction, in accordance with some embodiments. The fin spacer layers 119 are used to confine the growth of epitaxial material to prevent neighboring epitaxial material from merging with each other, in accordance with some embodiments.

In some embodiments, the gate spacer layers 118 and the fin spacer layers 119 are formed from one or more continuous dielectric material(s). For example, in some embodiments, the formation of the gate spacer layers 118 and the fin spacer layers 119 includes globally and conformally depositing a dielectric material over the semiconductor structure 100 using ALD, CVD (such as LPCVD, PECVD or HDP-CVD or a combination thereof, followed by an anisotropic etching process, in accordance with some embodiments.

In some embodiments, the dielectric material may be silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the gate spacer layers 118 may include air gaps and/or a porous version of the above-mentioned dielectric materials.

After the anisotropic etching process, the vertical portions of the dielectric material left remaining on the opposite sides of the dummy gate structures 112 form the gate spacer layers 118, while the vertical portions of the dielectric material left remaining on the opposite sides of the active regions 104N and 104P form the fin spacer layers 119, in accordance with some embodiments. In some embodiments, the gate spacer layers 118 has a thickness (i.e., the dimension in the X direction) in a range from about 3 nm to about 12 nm.

FIGS. 3B-1 to 3B-3 illustrate a semiconductor structure 100 after the formation of source/drain recess 120, in accordance with some embodiments.

An etching process is performed to recess the source/drain regions of the active regions 104N and 104P, thereby forming source/drain recesses 120, as shown in FIGS. 3B-2 and 3B-3, in accordance with some embodiments. The etching process may be an anisotropic etching process such as dry plasma etching, an isotropic etching process such as dry chemical etching, remote plasma etching or wet chemical etching, and/or a combination thereof. The gate spacer layers 118 and the dummy gate structures 112 may serve as etch masks such that the source/drain recesses 120 are formed self-aligned on opposite sides of the dummy gate structures 112, in accordance with some embodiments.

In some embodiments, the bottom of the source/drain recess 120 may extend into the lower fin elements 103N and 103P. The fin spacer layers 119 are also recessed in the etching process, in accordance with some embodiments.

FIGS. 3C-1 to 3C-3 illustrate a semiconductor structure 100 after the formation of inner spacer layers 122 and dielectric separation layers 124.

An etching process is performed to laterally recess, from the source/drain recesses 120, the first semiconductor layers 106 of the active regions 104N and 104P, thereby forming notches, and then inner spacer layers 122 are formed in the notches, as shown in FIG. 3C-3 in accordance with some embodiments. The inner spacer layers 122 abut the recessed side surfaces of the first semiconductor layers 106, in accordance with some embodiments. The inner spacer layers 122 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 122 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the inner spacer layers 122 may include air gaps and/or a porous version of the above-mentioned dielectric materials. In some embodiments, the inner spacer layers 122 are made of different material than the gate spacer layers 118. In some embodiments where the inner spacer layers 122 and the gate spacer layers 118 are multi-layered structures, the effective dielectric constant of the inner spacer layers 122 is higher than the effective dielectric constant of the gate spacer layers 118.

In some embodiments, the inner spacer layers 122 are formed by depositing a dielectric material to fill the notches using ALD, CVD (such as PECVD, LPCVD or HARP), another suitable technique, or a combination thereof, and the dielectric material outside the notches are then etched away using an anisotropic etching process such as dry plasma etching, an isotropic etching process such as dry chemical etching, remote plasma etching or wet chemical etching, or a combination thereof. In some embodiments, the inner spacer layers 122 has a thickness (i.e., the dimension in the X direction) in a range from about 2 nm to about 10 nm.

Dielectric separation layers 124 are formed on the lower fin elements 103N and 103P, as shown in FIGS. 3C-2 and 3C-3, in accordance with some embodiments. In some embodiments, the dielectric separation layers 124 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN).

In some embodiments, the dielectric separation layers 124 are formed by depositing a dielectric material over the semiconductor structure 100, followed by an etching-back processes. In some embodiments, the dielectric separation layers 124 abut the sidewalls of the bottommost first semiconductor layers 106. In some embodiments, the top surfaces of the dielectric isolation layers are lower than the bottom surfaces of the bottom second semiconductor layer 108_3. In some other embodiments, the dielectric separation layers 124 is only formed in the p-type well PW, but not in the n-type well. In some embodiments where the source/drain recesses 120 extend into the lower fin elements, semiconductor separation layers (not shown) may be grown on the lower fin elements before the dielectric separation layers 124 are formed. In an embodiment, the semiconductor isolation layers are made of non-doped silicon.

FIGS. 3D-1 to 3D-3 illustrate a semiconductor structure 100 after the formation of source/drain features 126N and 126P, a contact etching stop layer 128 and a first interlayer dielectric layer 130, and fin-cut structures 132, in accordance with some embodiments.

Source/drain features 126N are grown from the exposed side surfaces of the second semiconductor layers 108 in the p-type well PW and source/drain features 126P are grown from the exposed side surfaces of the second semiconductor layers 108 in the n-type well NW using one or more epitaxial growth processes, as shown in FIG. 3D-2 and 3D-3, in accordance with some embodiments. The epitaxial growth processes may be MBE, MOCVD, or VPE, or another suitable technique.

The source/drain features 126N and 126P fill the source/drain recesses 120, in accordance with some embodiments. The source/drain features 126N abut the second semiconductor layers 108 of the active region 104N and the inner spacer layers 122, and the source/drain features 126P abut the second semiconductor layers 108 of the active region 104P and the inner spacer layers 122, in accordance with some embodiments. In some embodiments, the thickness (i.e., the dimension in the Z direction) of the source/drain feature is different from the width (i.e., the dimension in the Y direction) of the source/drain feature, as shown in FIG. 3D-2.

In some embodiments, the source/drain features 126N and the source/drain features 126P may be formed separately. For example, a patterned mask layer (such as a photoresist layer and/or a hard mask layer) may be formed to cover the semiconductor structure 100 over the n-type well NW, and then the source/drain features 126N are grown. Afterward, the patterned mask layer may be removed. Similarly, a patterned mask layer (such as a photoresist layer and/or a hard mask layer) is formed to cover the semiconductor structure 100 over the p-type well PW, and then the source/drain features 126P are grown. Afterward, the patterned mask layer may be removed. In some embodiments, the source/drain features 126N and 126P are in-situ doped during the epitaxial processes.

In some embodiments, the source/drain features 126N are made of semiconductor epitaxial material such as SiP, SiAs, SiCP, SiC, Si, GaAs, another suitable semiconductor material, or a combination thereof. In some embodiments, the source/drain features 126N are doped with the n-type dopant during the epitaxial growth process. For example, the n-type dopant may be phosphorous (P) or arsenic (As). For example, the source/drain features 126N may be the epitaxially grown Si doped with phosphorous to form silicon: phosphor (Si:P) source/drain features and/or arsenic to form silicon: arsenic (Si:As) source/drain feature. In some embodiments, the concentration of the dopants (e.g., P) in the source/drain features 126N is in a range from about 2×10¹⁹/cm⁻³ to about 3×10²¹/cm⁻³.

The source/drain features 126P are made of semiconductor material such as SiGe, Si, GaAs, another suitable semiconductor material, or a combination thereof. In some embodiments, the source/drain features 126P are doped with the p-type dopant during the epitaxial growth process. For example, the p-type dopant may be boron (B) or BF₂. For example, the source/drain features 126P may be the epitaxially grown SiGe doped with boron (B) to form silicon germanium: boron (SiGe: B) source/drain feature. In some embodiments, the concentration of the dopants (e.g., B) in the source/drain features 126P is in a range from about 1×10¹⁹/cm⁻³ to about 6×10²⁰/cm⁻³.

A contact etching stop layer 128 is formed over the semiconductor structure 100 to cover the source/drain features 126N and 126P, as shown in FIGS. 3D-2 and 3D-3, in accordance with some embodiments. In some embodiments, the contact etching stop layer 128 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material.

In some embodiments, the contact etching stop layer 128 is globally deposited using ALD, CVD (such as LPCVD, PECVD, HDP-CVD and HARP), another suitable method, and/or a combination thereof. In some embodiments, the dielectric constant of the contact stop layer 128 is greater than the dielectric constant of the inner spacer layers 122 and the dielectric constant of the gate spacer layers 118.

A first interlayer dielectric layer 130 is formed over the contact etching stop layer 128, as shown in FIGS. 3D-1 and 3D-2, in accordance with some embodiments. The first interlayer dielectric layer 130 overfills the space between dummy gate structures 112, in accordance with some embodiments. In some embodiments, the first interlayer dielectric layer 130 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the dielectric constant of the contact stop layer 128 is greater than the dielectric constant of the first interlayer dielectric layer 130. In some embodiments, the thickness of the portion of the contact stop layer 128 along the gate spacer layer 128 and the source/drain features 124N and 124P is less than the thickness (i.e., dimension in the Z direction) and the width (i.e., dimension in the X and Y directions) of the first interlayer dielectric layer 130.

In some embodiments, the dielectric material for the first interlayer dielectric layer 130 is deposited using such as CVD (such as HDP-CVD, PECVD, HARP or FCVD), another suitable technique, or a combination thereof. The dielectric materials for the contact etching stop layer 128 and the first interlayer dielectric layer 130 above the top surface of the dummy gate electrode layer 116 are removed using such as CMP, in accordance with some embodiments.

Two of the dummy gate structures 112 formed on the cell boundary are replaced with fin-cut structures 132, as shown in FIG. 3D-3, in accordance with some embodiments. The fin-cut structures 132 are formed to penetrate through the dummy gate structures 112 and the underlying active regions 104N and 104P, in accordance with some embodiments. In some embodiments, the fin-cut structures 132 extend in the Y direction. In some embodiments, the fin-cut structures 132 are configured to prevent leakage between the neighboring cell regions. The fin-cut structures 132 may be also referred to as cut poly gate on oxide definition edge (CPODE) pattern.

The fin-cut structures 132 are made of a dielectric material such as silicon oxide (SiO₂), silicon oxynitride (SiON), silicon nitride (SiN), silicon carbon nitride (SiCN), silicon oxycarbonitride (SiOCN), oxygen-doped silicon carbonitride (Si(O)CN), or a combination thereof. In some embodiments, the fin-cut structures 132 include dielectric material with k-value greater than 7.9, such as LaO, AlO, AlON, ZrO, HfO, ZnO, ZrN, ZrAlO, TiO, TaO, YO, TaCN, or a combination thereof.

The formation of the fin-cut structures 132 includes patterning the dummy gate structures 112 and the active regions 104N and 104P using photolithography and etching processes to form cutting trenches, depositing a dielectric material for the fin-cut structures 132 to overfill the cutting trenches, in accordance with some embodiments. A planarization process (e.g., CMP, etching back process, or a combination thereof) is then performed on the dielectric material until the first interlayer dielectric layer 130 is exposed, in accordance with some embodiments.

FIGS. 3E-1 to 3E-3 illustrate a semiconductor structure 100 after the formation of a gate trench 134 and gaps 136, in accordance with some embodiments.

One or more etching processes are performed to remove the dummy gate structure 112 to form a gate trench 134 and remove the first semiconductor layers 106 of the active regions 104N and 104P to form gaps 136, in accordance with some embodiments. In some embodiments, the gate trench 134 exposes the channel regions of the active regions 104N and 104P. In some embodiments, the gate trench 134 further exposes the sidewalls of the gate spacer layers 118 facing the channel region. In some embodiments, the gaps 136 expose the sidewalls of the inner spacer layers 122 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 of the active region 104N and 104P form nanostructures 108, in accordance with some embodiments. As the term is used herein, “nanostructures” refers to the semiconductor layers with cylindrical shape, bar shaped and/or sheet shape.

In some embodiments, the etching process for removing the first semiconductor layers 106 may include the over-etching step to entirely remove the first semiconductor layers 106, preventing the SiGe remainder of the first semiconductor layers 106 from being left on the silicon channels. In the over-etching step, the center portion the nanostructures 108 exposed from the gate trench 134 and the gaps 136 are also recessed (or thinned down). As such, the end portions of the nanostructures 108 (also referred to as LDD (lightly doped drain) regions) surrounded by the gate spacer layers 118 and the inner spacer layers 122 are thicker than (and wider than, shown in FIG. 3F-4) the center portions of the nanostructures 108, in accordance with some embodiments. In some embodiments, each of the nanostructures 108 has a dumbbell shape in the cross-section that is along and through the active region, as shown in FIG. 3E-1.

In alternative embodiments, a treatment process is performed to thin down the center portion the nanostructures 108 after the first semiconductor layers 106 are removed. The treatment process may be an isotropic etching process such as dry chemical etching, remote plasma etching or wet chemical etching, and/or a combination thereof.

FIGS. 3F-1 to 3F-3 illustrate a semiconductor structure 100 after the formation of a final gate stack 138 and gate-cut structures 146.

A final gate stack 138 is formed in the gate trench 134 and gaps 136, and it is thereby wrapped around the nanostructures 108, as shown in FIGS. 3F-1 and 3F-3, in accordance with some embodiments. In some embodiments, the final gate stack 138 extends in the Y direction. The final gate stack 138 engages the channel region so that current can flow between the source/drain regions during operation. In some embodiments, the final gate stack 138 includes an interfacial layer 140, a gate dielectric layer 142 and a metal gate electrode layer 144, as shown in FIGS. 3F-1 and 3F-3, in accordance with some embodiments.

The interfacial layer 140 is formed on the exposed surfaces of the nanostructures 108 and the exposed surfaces of the lower fin elements 103N and 103P, in accordance with some embodiments. The interfacial layer 140 wraps around the nanostructures 108, in accordance with some embodiments. In some embodiments, the interfacial layer 140 is made of a chemically formed silicon oxide. In some embodiments, the interfacial layer 140 is nitrogen-doped silicon oxide. In some embodiments, the interfacial layer 140 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 103N and 103P is oxidized to form the interfacial layer 140, in accordance with some embodiments.

The gate dielectric layer 142 is formed conformally along the interfacial layer 140 to wrap around the nanostructures 108, in accordance with some embodiments. The gate dielectric layer 142 is further formed along the exposed sidewalls of the gate spacer layers 118 and the inner spacer layers 122 facing the channel region, in accordance with some embodiments. The gate dielectric layer 142 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Si₃N₄, oxynitrides (SiON), a combination thereof, or another suitable material. The high-k dielectric layer may be deposited using ALD, PVD, CVD, or another suitable technique. In some embodiments, the dielectric constant of the gate dielectric layer 142 is higher than the dielectric constant of the gate spacer layer 118. In some embodiments, the dielectric constant of the gate dielectric layer 142 is at least twice the dielectric constant of the first interlayer dielectric layer 130.

The metal gate electrode layer 144 is formed over the gate dielectric layer 142 and overfills the remainder of the gate trench 134 and the gaps 136, in accordance with some embodiments. In some embodiments, the metal gate electrode layer 144 is made of more than one conductive material, such as a metal, metal alloy, conductive metal oxide and/or metal nitride, another suitable conductive material, or a combination thereof. For example, the metal gate electrode layer 144 may be made of Ti, Ag, Al, TiAlN, TiAl, TiAlC, TaC, TaCN, TaSiN, Mn, Zr, TiN, TaN, Ru, Mo, WN, Cu, W, Re, Ir, Co, Ni, Pt, another suitable conductive material, or multilayers thereof. The metal gate electrode layer 144 may be a multi-layer structure with various combinations of a diffusion barrier layer, work function layers with a selected work function to enhance the device performance for n-channel FETs or p-channel FETs, a capping layer to prevent oxidation of work function layers, a glue layer, and a metal fill layer to reduce the total resistance of gate stacks, or another suitable layer.

A planarization process such as CMP may be performed on the semiconductor structure 100 to remove the materials of the gate dielectric layer 142 and the metal gate electrode layer 144 formed above the upper surface of the first interlayer dielectric layer 130, in accordance with some embodiments. The final gate stack 138 that are wrapped around the nanostructures 108 combine with the neighboring source/drain features 126N or 126P to form nanostructure transistors. In some embodiments, the transistors formed in the p-type well PW are the n-channel nanostructure transistor (NMOSFET in FIG. 2), and the transistors formed in the n-type well NW are the p-channel nanostructure transistor (PMOSFET in FIG. 2).

In some embodiments, the top nanostructure 108_1 is the thickest layer among the plurality of the nanostructures 108. In some embodiments, the center portions of the nanostructures 108_1, 108_2 and 108_3 surrounded by (or vertically overlapping) the gate stack 138 have thickness T1A, T2A and T3A, as shown in FIGS. 3F-1 and 3F-3, respectively. The end portions (i.e., LDD regions) the nanostructures 108_1, 108_2 and 108_3 surrounded by (or vertically overlapping) the gate spacer layers 118 and the inner spacer layers 122 have thickness T1B, T2B and T3B, as shown in FIG. 3F-3, respectively.

The thickness T1A of the center portion of the top nanostructure 108_1 is greater than the thickness T2A of the center portion of the middle nanostructure 108_2 and the thickness T3A of the center portion of the bottom nanostructure 108_3. In some embodiments, the ratio (T1A/T2A) of the thickness T1A to thickness T2A is in a range from about 1.05 to about 1.3. In some embodiments, the ratio (T1A/T3A) of the thickness T1A to thickness T3A is in a range from about 1.05 to about 1.3.

The thickness T1B of the end portion of the top nanostructure 108_1 is greater than the thickness T2B of the end portion of the middle nanostructure 108_2 and the thickness T3B of the end portion of the bottom nanostructure 108_3. In some embodiments, the ratio (T1B/T2B) of the thickness T1B to thickness T2B is in a range from about 1.05 to about 1.3. In some embodiments, the ratio (T1B/T3B) of the thickness T1B to thickness T3B is in a range from about 1.05 to about 1.3.

The thickness T1B of the end portion of the top nanostructure 108_1 is greater than the thickness T1A of the center portion of the top nanostructure 108_1. In some embodiments, the ratio (T1B/T1A) of the thickness T1B to thickness T1A is in a range from about 1.05 to about 1.3.

The thickness T2B of the end portion of the middle nanostructure 108_2 is greater than the thickness T2A of the center portion of the middle nanostructure 108_2. In some embodiments, the ratio (T2B/T2A) of the thickness T2B to thickness T2A is in a range from about 1.05 to about 1.3.

The thickness T3B of the end portion of the bottom nanostructure 108_3 is greater than the thickness T3A of the center portion of the bottom nanostructure 108_3. In some embodiments, the ratio (T3B/T3A) of the thickness T3B to thickness T3A is in a range from about 1.05 to about 1.3.

In some embodiments, the thickness T2A may be less than, equal to or greater than the thickness T3A. In some embodiments, the thickness T2B may be less than, equal to or greater than the thickness T3B.

FIG. 3F-4 is a plan view illustrating the semiconductor structure of FIG. 3F-1 taken along plane A-A. In some embodiments, the width W1B (i.e., the dimension in the Y direction) of the end portion of the nanostructure 108 (e.g., 108_1) is greater than the width W1A of the center portion of the nanostructure 108 (e.g., 108_1). In some embodiments, the ratio (W1B/W1A) of the width W1B to width W1A is in a range from about 1.05 to about 1.3. In some embodiments, each of the nanostructures 108 has a dumbbell shape in the plan section that is along and through the active region, as shown in FIG. 3F-4.

The interface between the nanostructure 108 and the interfacial layer 140 may be curved, in accordance with some embodiments. The gate dielectric layer 142 extends into and is surrounded by the nanostructure 108, as shown in FIGS. 3F-3 and 3F-4, in accordance with some embodiments.

Gate-cut structures 146 are formed through the final gate stack 138 and the gate spacer layers 118, the contact etching stop layer 128, the first interlayer dielectric layer 130 and the isolation structure 110, as shown in FIGS. 3F-1 and 3F-2, in accordance with some embodiments. In some embodiments, the gate-cut structures 146 extend into the wells NW and PW. In some embodiments, the gate-cut structures 146 extend in the X direction. The final gate stack 138 is cut through by the gate-cut structures 146 into several segments which are physically and electrically isolated from each other, in accordance with some embodiments. The gate-cut structures 146 may be also referred to as cut metal gate (CMG) patterns.

The gate-cut structures 146 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate-cut structures 146 include dielectric material with a dielectric constant value greater than 7.9, such as LaO, AlO, AlON, ZrO, HfO, ZnO, ZrN, ZrAlO, TiO, TaO, YO, TaCN, or a combination thereof. The formation of the gate-cut structures 146 includes patterning the semiconductor structure 100 to form gate-cut openings using photolithography and etching processes, depositing a dielectric material to overfill the gate-cut openings, in accordance with some embodiments. A planarization process (e.g., CMP, etching back process, or a combination thereof) is then performed on the dielectric material until the first interlayer dielectric layer 130 is exposed, in accordance with some embodiments.

FIGS. 3G-1 to 3G-5 illustrate a semiconductor structure 100 after the formation of a second interlayer dielectric layer 148 and contact openings 150′, in accordance with some embodiments.

A second interlayer dielectric layer 148 is formed over the semiconductor structure 100, as shown in FIGS. 3G-1 to 3G-5, in accordance with some embodiments. In some embodiments, the second interlayer dielectric layer 148 is made of dielectric material, such as USG, BPSG, FSG, PSG, BSG, or another suitable dielectric material. In some embodiments, the second interlayer dielectric layer 148 is deposited using such as CVD (such as HDP-CVD, PECVD, HARP or FCVD), another suitable technique, or a combination thereof.

The second interlayer dielectric layer 148, the first interlayer dielectric layer 130 and the contact etching stop layer 128 are patterned to form contact openings 150′, as shown in FIGS. 3G-2 to 3G-5, in accordance with some embodiments. The contact openings 150′ correspond to and expose the top surfaces of the source/drain features 126N and 126P, in accordance with some embodiments. In some embodiments, the portion of the contact etching stop layer 128 along the sidewalls of the gate spacer layers 118 is also removed to expose the gate spacer layers 118, as shown in FIGS. 3G-3 and 3G-5. In some other embodiments, the contact etching stop layer 128 may remain on the sidewalls of the gate spacer layers 118 after the patterning process. In some embodiments, the gate-cut structures 146 are also exposed from the contact openings 150′, as shown in FIG. 3G-4.

The patterning process includes forming a photoresist (not shown) such as by using spin-on coating, and then patterning the photoresist to have opening patterns corresponding to the contact openings 150′ by exposing the photoresist to light using an appropriate photomask (or reticle). Exposed or unexposed portions of the photoresist may be removed depending on whether a positive or negative resist is used. The opening patterns of the photoresist may then be transferred to the second interlayer dielectric layer 148, the first interlayer dielectric layer 130 and the contact etching stop layer 128, such as by using one or more suitable etch processes. The photoresist can be removed in an ashing or wet strip process, for example.

In alternative embodiments, a hard mask layer (not shown) may be formed on semiconductor structure 100. The hard mask layer may include, or be formed of, a nitrogen-free anti-reflection layer (NFARL), carbon-doped silicon dioxide (e.g., SiO₂:C), titanium nitride (TiN), titanium oxide (TiO), aluminum oxide (AlO), boron nitride (BN), a multilayer thereof, another suitable material, and/or a combination thereof. The hard mask layer may be etched using a patterned photoresist layer, which may be formed by the photolithography described above, thereby having the opening patterns corresponding to the contact openings 150′. The patterned hard mask layer may transfer the opening patterns to the second interlayer dielectric layer 148, the first interlayer dielectric layer 130 and the contact etching stop layer 128, which may be accomplished by using one or more suitable etch processes.

The etch processes may include dry etching such as a reactive ion etch (RIE), neutral beam etch (NBE), inductive coupled plasma (ICP) etch, another suitable method, or a combination thereof. The etch processes may be anisotropic. In some embodiments, the source/drain features 126N and 126P may be slightly recessed in the etching process.

FIGS. 3H-1 to 3H-5 illustrate a semiconductor structure 100 after the formation of contact liners 152, in accordance with some embodiments.

Contact liners 152 are formed in the contact openings 150′, as shown in FIGS. 3H-2 to 3H-5, in accordance with some embodiments. The contact liners 152 extend along the sidewalls of the contact openings 150′ and partially fill the contact openings 150′, in accordance with some embodiments.

In some embodiments, the contact liners 152 are made of dielectric material such as nitrogen-containing dielectric material such as silicon nitride (SiN), silicon oxynitride (SiON), silicon carbon nitride (SiCN), silicon oxycarbonitride (SiOCN), and/or oxygen-doped silicon carbonitride (Si(O)CN), or a combination thereof. The nitrogen-containing dielectric material may have better etch resistance to protect the gate spacer layers 118 from being damaged during the source/drain clean process.

In some embodiments, the formation of the contact liners 152 includes depositing the dielectric material using ALD, CVD (such as LPCVD, PECVD or HDP-CVD), another suitable method, and/or a combination thereof, and etching-back the dielectric material to remove the dielectric material from the top surface of the second interlayer dielectric layer 148 and the bottom surface of the contact openings 150′. The top surfaces of the source/drain features 126N and 126P are exposed from the contact openings 150′ again, in accordance with some embodiments.

FIGS. 3I-1 to 3I-5 illustrate a semiconductor structure 100 after an etching process, in accordance with some embodiments.

An etching process is performed on the semiconductor structure 100 to vertically enlarge the contact openings 150′, as shown in FIGS. 3I-2 to 3I-5, in accordance with some embodiments. The source/drain features 126N and 126P are etched thereby extending the contact openings 150′ to a deeper position, in accordance with some embodiments. The enlarged contact openings 150′ are denoted as 150. The etching processes may include an anisotropic etching process such as dry plasma etching, an isotropic etching process such as dry chemical etching, remote plasma etching or wet chemical etching, or a combination thereof.

In some embodiments, the bottom surfaces of the contact openings 150 are located lower than the bottom surfaces of the top nanostructures 108_1. In some embodiments, the bottom surfaces of the contact openings 150 are located at a level between the top surfaces and the bottom surfaces of the middle nanostructures 108_2.

The contact openings 150 include upper portions 150A and lower portions 150B, as shown in FIG. 3I-3, in accordance with some embodiments. The upper portions 150A penetrate through the second interlayer dielectric layer 148, the first interlayer dielectric layer 130 and the contact etching stop layer 128, in accordance with some embodiments. The lower portions 148B penetrate through the upper portions of source/drain features 126N and 126P, in accordance with some embodiments.

In some embodiments, the sidewalls of the upper portion 150A are substantially straight or linear. In some embodiments, the sidewalls of the upper portion 150A are substantially perpendicular to or sloped relative to a plane parallel to the top surface of the substrate 102. In some embodiments, the sidewalls of the lower portion 150B are substantially straight or linear. In some embodiments, the sidewalls of the upper portion 150A are sloped relative to the plane parallel to the top surface of the substrate 102.

FIGS. 3J-1 to 3J-5 illustrate the semiconductor structure 100 after the formation of contact structures 154, in accordance with some embodiments. FIG. 3J-6 is a plan view illustrating the semiconductor structure 100 of FIG. 3J-1 taken along plane A-A.

Silicide layers 156 are formed on the exposed top surfaces of the source/drain features 126N and 126P, as shown in FIGS. 3J-2 to 3J-6, in accordance with some embodiments. In some embodiments, the silicide layers 156 formed on the n-type source/drain features 126N are made of WSi, NiSi, TiSi and/or CoSi. In some embodiments, the silicide layers 156 formed on the p-type source/drain features 126P are made of WSiGe, NiSiGe, TiSiGe and/or CoSiGe.

In some embodiments, the formation of the silicide layers 156 includes pre-cleaning the exposed surface of the source/drain features 126N and 126P, depositing a metal material followed by one or more annealing processes. The semiconductive material (e.g., Si or SiGe) from the source/drain features 126N and 126P reacts with the metal material to form the silicide layers 156, in accordance with some embodiments. The unreacted metal material is then removed using a post-cleaning process.

Contact structures 154 are formed in the contact openings 150 on the silicide layers 156, as shown in FIGS. 3J-2 to 3J-6, in accordance with some embodiments. The contact structures 154 land on the source/drain features 126N and 126P and extends into the source/drain features 126N and 126P, in accordance with some embodiments. The source/drain features 126N and 126P each include a portion sandwiched between the silicide layer 156 and the top nanostructure 108_1, as shown in FIG. 3J-6, in accordance with some embodiments. In the Y direction, the dimension of the silicide layer 156 is greater than the width W1B of the end portion of the top nanostructure 108_1, as shown in FIG. 3J-6, in accordance with some embodiments.

The contact structures 154 may have a multilayer structure. For example, one or more conductive materials include a barrier/adhesive layer and a metal bulk layer on the barrier/adhesive layer. In some embodiments, the barrier/adhesive layer may be made of tantalum (Ta), tantalum nitride (TaN), titanium (Ti), titanium nitride (TiN), cobalt tungsten (CoW), another suitable material, or a combination thereof. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

In some embodiments, one or more conductive materials are deposited using CVD, PVD, e-beam evaporation, ALD, electroplating (ECP), electroless deposition (ELD), another suitable method, or a combination thereof to overfill the contact openings. In some embodiments, the metal bulk layer is formed using a selective deposition technique such as cyclic CVD process or ELD process, and it is not necessary to form the barrier/adhesive layer before depositing the metal bulk material.

The one or more conductive materials over the top surface of the first interlayer dielectric layer 130 are planarized using, for example, CMP until the gate electrode layer 144 is exposed. The second interlayer dielectric layer 148 is also removed, in accordance with some embodiments. In some embodiments, the top surface of the gate electrode layer 144 is leveled with the top surfaces of the contact structures 154 and the top surface of the first interlayer dielectric layer 130.

In some embodiments, the electrical conductivity of the contact structure 154 is greater than the electrical conductivity of the silicide layer 156, and the electrical conductivity of the silicide layer is greater than the electrical conductivity of the source/drain features 124N and 124D.

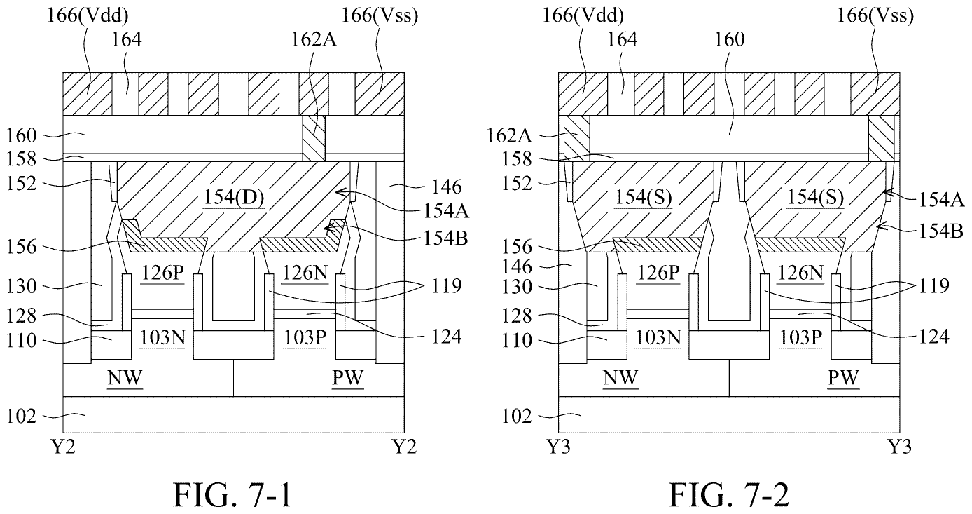

FIG. 3J-7 is an enlarged view of FIG. 3J-5, in accordance with some embodiments of the disclosure. In some embodiments, the silicide layer 156 has a V-shape or U-shape in the cross-sectional view. The contact structure 154 may have a kinked profile, in accordance with some embodiments. As the term is used herein, “kink” refers to a pattern extending in a direction, with a dent or protrusion on one or both sides of the pattern. The contact structures 154 with the kink structure may include narrower portions and wider portions, in accordance with some embodiments. The contact structure 154 includes an upper portion (wider portion) 154A and a lower portion (narrower portion) 154B, in accordance with some embodiments.

The upper portion 154A is surrounded by the contact liners 152, in accordance with some embodiments. The bottom of the upper portion 154A is substantially level with the bottom of the contact liners 152, in accordance with some embodiments. The lower portion 154B is surrounded by the silicide layer 156, in accordance with some embodiments. In some embodiments, the bottom surface of the lower portion 154B is lower than the bottom surface of the top nanostructure 108. In some embodiments, the bottom surface of the silicide layer 156 is located at a level between the top surface and the bottom surface of the middle nanostructure 108_2.

In some embodiments, the sidewalls 154S1 of the upper portion 154A are substantially straight or linear. In some embodiments, the sidewalls 154S1 of the upper portion 154A are substantially perpendicular to or sloped relative to the plane parallel to the top surface of the substrate 102. In some embodiments, the sidewalls 154S2 of the lower portion 154B are substantially straight or linear. In some embodiments, the sidewalls 154S2 of the lower portion 154B are sloped relative to the plane parallel to the top surface of the substrate 102. In some embodiments, the slope of the sidewall 154S2 is different from the slope of the sidewall 154S1 in the cross-section that is along and through the active region, as shown in FIG. 3J-7. For example, the slope of the sidewall 154S2 is less than the slope of the sidewall 154S1.

The contact structure 154 has a connecting wall 154W which is connected to the sidewall 154S1 of the upper portion 154A and the sidewall 154S2 of the lower portion 154B, in accordance with some embodiments. In some embodiments, the connecting wall 154W extends horizontally. In some other embodiments, the connecting wall 154W extends obliquely to the plane parallel to the top surface of the substrate 102. In some other embodiments, the connecting wall 154W is curved.

As a result, the sidewall 154S2 of the lower portion 154B is not coplanar with the sidewall 154S1 of the upper portion 154A. The sidewall 154S2 of the lower portion 154B is indented from the sidewall 154S1 of the upper portion 154A by a distance that is the distance D5 the connecting wall 154W extends horizontally, in accordance with some embodiments.

In some embodiments, the dimension of the upper portion 154A in the X direction maintains consistent or decreases in the direction toward the bottom of the contact structure 154. For example, the upper portion 154A has a dimension D1 in the X direction at the top of the upper portion 154A and a dimension D2 in the X direction at the bottom of the upper portion 154A (where the connecting wall 154W is located). The dimension D2 is equal to or less than the dimension D1.

In some embodiments, the dimension of the lower portion 154B in the X direction decreases in the direction toward the bottom of the contact structure 154. For example, the lower portion 154B has a dimension D3 in the X direction at the top of the lower portion 154B (where the connecting wall 154W is located) and a dimension D4 in the X direction at the bottom of the lower portion 154B. The dimension D3 is greater than the dimension D4, and less than the dimension D2 by the distance D5. In some embodiments, the distance D5 is about 1-10 nm. In some embodiments, the ratio (D2/D3) of the dimension D2 to the dimension D3 is in a range from about 1.1 to about 2.

Referring back to FIGS. 3J-2 and 3J-4, in some embodiments, the upper portion of the contact structure 154 surrounded by the contact liner 152 and the lower portion of the contact structure 154 under the contact liner 152 may have the same dimension in the Y direction. In some other embodiments, the upper portion and the lower portion 154B of the contact structure 154 may have different dimensions in the Y direction.

FIGS. 3K-1 to 3K-5 illustrate a semiconductor structure 100 after the formation of an etching stop layer 158, a third interlayer dielectric layer 160, vias 162A and 162B, an intermetal dielectric layer 164 and metal lines 166, in accordance with some embodiments.

An etching stop layer 158 and a third interlayer dielectric layer 160 are sequentially formed over the semiconductor structure 100, as shown in FIGS. 3K-1 to 3K-5, in accordance with some embodiments. In some embodiments, the etching stop layer 158 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the third interlayer dielectric layer 160 is made of dielectric material, such as USG, BPSG, FSG, PSG, BSG, and/or another suitable dielectric material. In some embodiments, the etching stop layer 158 and the third interlayer dielectric layer 160 are deposited using CVD (such as HDP-CVD, PECVD, HARP or FCVD), another suitable technique, or a combination thereof.

Vias 162A are formed through the third interlayer dielectric layer 160 and the etching stop layer 158 and land on the contact structures 154, and a via 162B is formed through the third interlayer dielectric layer 160 and the etching stop layer 158 and lands on the gate stack 138, as shown in FIGS. 3K-1 to 3K-5, in accordance with some embodiments. The vias 162A, electrically connected to source/drain terminals of the nanostructure transistors through the contact structures 154, may be also referred to as source/drain vias (VS or VD), in accordance with some embodiments. The via 162B, electrically connected to the gate terminals of the nanostructure transistors, may be also referred to as gate via (VG).

In some embodiments, the formation of the vias 162A and 162B includes patterning the semiconductor structure 100 to form via openings using photolithography and etching processes. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the third interlayer dielectric layer 160 are planarized using, for example, CMP.

The vias 162A and 162B may have a multilayer structure. For example, a barrier/adhesive layer (not shown) may optionally be deposited along the sidewalls and the bottom surfaces of the via openings. The barrier layer may be made of Ta, TaN, Ti, TiN, CoW, another suitable material, or a combination thereof. A metal bulk layer is then deposited on the barrier/adhesive layer (if formed) to fill the remainder of the via openings. In some embodiments, the metal bulk layer is made of one or more conductive materials, such as Co, Ni, W, Ti, Ta, Cu, Rh, Ir, Pt, Al, Ru, Mo, or a combination thereof.

An intermetal dielectric layer 164 is formed over the vias 162A and 162B and the third interlayer dielectric layer 160, and metal lines 166 of a first-level metal layer (M1) are formed through the intermetal dielectric layer 164, as shown in FIGS. 3K-1 to 3K-5, in accordance with some embodiments. The metal lines 166 extend in the X direction, in accordance with some embodiments. The Vss power rail 166 is electrically connected to the n-type source/drain feature 126N, and the Vdd power rail 166 is electrically connected to the contact structure 154(S) for the p-type source/drain feature 126P, in accordance with some embodiments.

In some embodiments, the intermetal dielectric layer 164 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the intermetal dielectric layer 164 is made of an extremely low-k (ELK) dielectric material with a dielectric constant (k) less than about 3.0, or even less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂). In some embodiments, the intermetal dielectric layer 164 is formed using CVD (such as LPCVD, HARP, and FCVD), ALD, spin-on coating, another suitable method, or a combination thereof. A post-curing process (e.g., UV curing) may be performed on the as-deposited ELK dielectric material for the intermetal dielectric layer 164 to form a porous structure.

In some embodiments, the formation of the metal lines 166 includes patterning the semiconductor structure 100 to form trenches using photolithography and etching processes. Afterward, one or more conductive materials are deposited using CVD, PVD, e-beam evaporation, ALD, ECP, ELD, another suitable method, or a combination thereof to overfill the trenches, in accordance with some embodiments. The one or more conductive materials over the upper surface of the intermetal dielectric layer 164 are planarized using, for example, CMP. The metal lines 166 may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

As the scale of the semiconductor devices continues to shrink, the overall resistance of the source/drain region becomes one of the key factors affecting the performance of the semiconductor devices. For example, because the top channel is closer to the contact structure, the top channel may provide a shorter current path (i.e., lower resistance) and receive more current flow than other underlying channels, and thus the current crowding at the interface between the top channel LDD region and the epitaxial source/drain features is becoming more and more of a concern.

In the embodiments of the present disclosure, the top nanostructure 108_1 is the thickest among all nanostructures 108, which may provide lower resistance between the LDD region and the source/drain region, thereby alleviating the current crowding issue. Furthermore, each of the nanostructures 108 includes a thicker end portion (e.g., LDD region) and a thinner center portion (channel region). The thicker end portion may reduce the resistance at the interface between the channel and source/drain region, while the thinner center portion may help enhance the gate control over the channel. Therefore, the performance (e.g., speed) and/or reliability (e.g., drain-induced barrier lowering (DIBL)) of the resulting semiconductor device may improve.

In addition, a deep extension of the contact structures 154 may reduce the parasitic resistance of the resulting semiconductor device, and may increase the landing area of the contact structure 154 with the source/drain features 126N and 126P, and/or reduce the current path. As the scale of the semiconductor devices continues to shrink, the critical dimension of the contact structures becomes smaller and smaller. Due to the characteristics of the etching process, the larger the critical dimension of the contact opening (or opening pattern), the greater the etching amount. To form deeper contact openings in an etching process, the contact openings need to be defined with a larger critical dimension. However, the contact openings with a larger critical dimension may cause the resulting contact structures to touch the channels and/or the inner spacer layers without silicide formation, which may significantly increase the resistance.

In accordance with the embodiments of the present disclosure, the contact openings 150 are formed using two separate etching processes which are respectively performed before and after the formation of the contact liner 152. As a result, the contact structure 154 may extend to a deep position while preventing the contact structure from coming into contact with the channels and/or the inner spacer layers. Therefore, the performance and/or the reliability of the resulting semiconductor device may be enhanced, e.g., higher DC performance and/or lower leakage.

In addition, the top surface of the gate electrode layer 144 is level with the top surfaces of the contact structures 154, which may reduce the fringe parasitic capacitance. The performance (e.g., speed) of the resulting semiconductor device may be further improved.

FIG. 4 illustrates a semiconductor structure that is a modification of the semiconductor structure 100 of FIG. 3K-3, in accordance with some embodiments of the disclosure. The embodiments of FIG. 4 are similar to the embodiments of FIGS. 3A-1 through 3K-5 except that the contact structure 154 has a narrower dimension in the X direction. In some embodiments, the contact etching stop layer 128 remains on the sidewalls of the gate spacer layers 118 after the patterning process for forming the contact opening 150. The contact liners 152 are formed along the sidewalls of the contact etching stop layer 128, in accordance with some embodiments.

FIG. 5 illustrates a semiconductor structure that is a modification of the semiconductor structure 100 of FIG. 3K-2, in accordance with some embodiments of the disclosure. The embodiments of FIG. 5 are similar to the embodiments of FIGS. 3A-1 through 3K-5 except that the fin spacer layers 119 are removed in the etching process for forming the source/drain recesses 120.

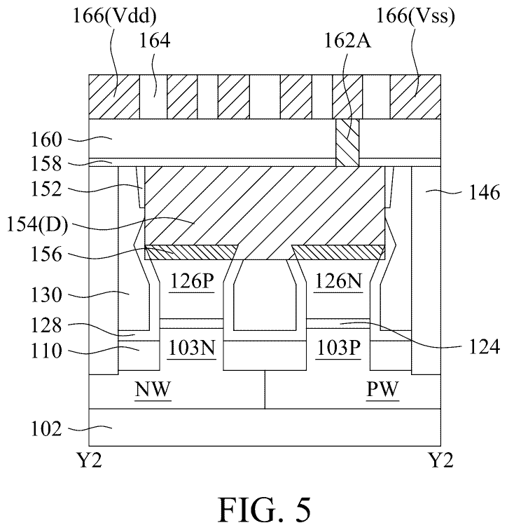

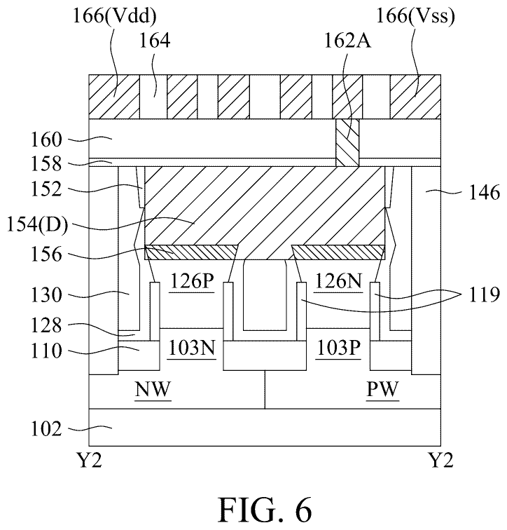

FIG. 6 illustrates a semiconductor structure that is a modification of the semiconductor structure 100 of FIG. 3K-2, in accordance with some embodiments of the disclosure. The embodiments of FIG. 6 are similar to the embodiments of FIGS. 3A-1 through 3K-5 except that the dielectric separation layers 122 are omitted. The source/drain features 126N and 126P are formed on and interfaced with the lower fin elements 103N and 103P, in accordance with some embodiments.

FIGS. 7-1 and 7-2 illustrates a semiconductor structure that is a modification of the semiconductor structure 100 of FIGS. 3K-2 and 3K-4, in accordance with some embodiments of the disclosure. The embodiments of FIGS. 7-1 and 7-2 are similar to the embodiments of FIGS. 3A-1 through 3K-5 except that the upper portion 154A of the contact structure 154 surrounded by the contact liner 152 and the lower portion 154B of the contact structure 154 under the contact liner 152 have different dimensions in the Y direction. In some embodiments, the dimension of the upper portion 154A in the Y direction maintains consistent in the direction toward the bottom of the contact structure 154, while the dimension of the lower portion 154B in the Y direction decreases in the direction toward the bottom of the contact structure 154.

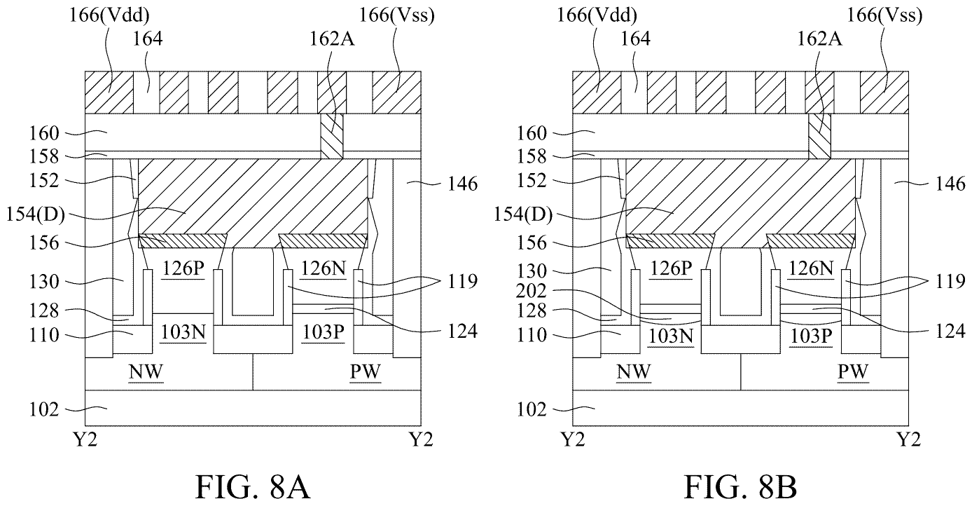

FIG. 8A illustrates a semiconductor structure that is a modification of the semiconductor structure 100 of FIG. 3K-2, in accordance with some embodiments of the disclosure. The embodiments of FIG. 8A are similar to the embodiments of FIG. 3K-2 except that the dielectric separation layers 124 is only formed in the p-type well PW, but not in the n-type well NW. In some embodiments, the source/drain feature 126P is formed on and in direct contact with the lower fin element 103N, as shown in FIG. 8A.

FIG. 8B illustrates a semiconductor structure that is a modification of the semiconductor structure 100 of FIG. 3K-2, in accordance with some embodiments of the disclosure. The embodiments of FIG. 8B are similar to the embodiments of FIG. 3K-2 except that semiconductor separation layers 202 are grown on the lower fin elements 103N and 103P before the dielectric separation layers 124 are formed. In some embodiments, the semiconductor isolation layers are made of non-doped silicon.

As described above, the aspect of the present disclosure is directed to a semiconductor structure including nanostructure transistors. The semiconductor structure includes nanostructures 108 surrounded by the gate stack 138 and source/drain features 126N/126P interfaced with the nanostructures 108. The top nanostructure 108_1 is the thickest among all nanostructures 108, which may alleviate the current crowding issue between the LDD region and the source/drain region. Furthermore, each of the nanostructures 108 includes a thicker end portion and a thinner center portion. The thicker end portion may reduce the resistance, and the thinner center portion may help enhance the gate control over the channel. Therefore, the performance and/or the reliability of the resulting semiconductor device may improve.

In addition, the semiconductor structure further includes a contact structure 154 extending into the source/drain feature 126N/126P. The contact opening 150 is formed using two separate etching processes. As a result, the contact structure 154 may extend to a deep position while preventing the contact structure from coming into contact with the channels and/or the inner spacer layers. Therefore, the performance and/or the reliability of the resulting semiconductor device may be enhanced. Furthermore, the top surface of the gate electrode layer 144 is level with the top surfaces of the contact structures 154, which may reduce the fringe parasitic capacitance. The performance (e.g., speed) of the resulting semiconductor device may be further improved.

Embodiments of a semiconductor structure and the method for forming the same may be provided. The semiconductor structure may include a gate stack wrapping around nanostructures, a source/drain feature adjoining the nanostructures, and a contact structure extending into the source/drain feature. The topmost nanostructure is thicker than other nanostructures, and the bottom surface of the contact structure is lower than the bottom surface of the topmost nanostructure. The current crowding issue may be alleviated, and thus the performance of the resulting semiconductor device may improve.

In some embodiments, a method for forming a semiconductor structure is provided. The method includes forming a first active region over a substrate. the first active region includes first semiconductor layers and second semiconductor layers alternatingly stacked, and a topmost one of the second semiconductor layers is thicker than the others of the second semiconductor layers. The method further includes forming a first source/drain feature on the first active region, forming a contact etching stop layer to cover the first source/drain feature, forming a first interlayer dielectric layer over the contact etching stop layer, removing the first semiconductor layers thereby forming nanostructures from second semiconductor layers, forming a gate stack to surround the nanostructures, and forming a contact opening through the first interlayer dielectric layer, the contact etching stop layer and the first source/drain feature. The first active region extends lengthwise along a first direction, and the gate stack extends lengthwise along a second direction that is different than the first direction. The gate stack includes a gate dielectric layer with a first dielectric constant, the first interlayer dielectric layer has a second dielectric constant, and the first dielectric constant is at least twice the second dielectric constant.

In some embodiments, a method for forming a semiconductor structure is provided. The method includes forming a transistor in a cell region of a substrate. The transistor includes first, second and third channel layers sequentially stacked a fin element, a source/drain feature on the fin element, a dielectric layer over the source/drain feature, and a gate stack surrounding the first, second and third channel layers. The third channel layer is thicker than the first channel layer and the second channel layer. The method further includes etching the dielectric layer to form an opening exposing the source/drain feature, extending the opening into the source/drain feature so that a bottom of the opening is lower than a bottom surface of the third channel layer, and forming a contact structure in the opening. An electrical conductivity of the contact structure is greater than an electrical conductivity of the source/drain feature.

In some embodiments, a semiconductor structure is provided. The semiconductor structure includes a plurality of nanostructures which includes a first nanostructure, a second nanostructure, and a third nanostructure sequentially stacked upwardly. The third nanostructure is thicker than the second nanostructure and the first nanostructure. The semiconductor structure further includes a gate stack, a source/drain feature, a dielectric layer, and a contact structure. The gate stack extends lengthwise along a first direction. The gate stack is wrapped around center portions of the nanostructures. The source/drain feature interfaces with end portions of the nanostructures. The dielectric layer is located over the source/drain feature. The contact structure passes through the dielectric layer and the source/drain feature. A thickness of the source/drain feature is different from a width of the source/drain feature in a cross-sectional view. A bottom surface of the contact structure is lower than a top surface of the second nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first active region over a substrate, wherein the first active region includes first semiconductor layers and second semiconductor layers alternatingly stacked, and a topmost one of the second semiconductor layers is thicker than the others of the second semiconductor layers;
forming a first source/drain feature on the first active region;
forming a contact etching stop layer to cover the first source/drain feature;
forming a first interlayer dielectric layer over the contact etching stop layer;
removing the first semiconductor layers, thereby forming nanostructures from the second semiconductor layers;
forming a gate stack to surround the nanostructures, wherein the first active region extends lengthwise along a first direction, and the gate stack extends lengthwise along a second direction that is different than the first direction, wherein the gate stack includes a gate dielectric layer with a first dielectric constant, the first interlayer dielectric layer has a second dielectric constant, and the first dielectric constant is at least twice the second dielectric constant; and
forming a contact opening through the first interlayer dielectric layer, the contact etching stop layer and the first source/drain feature.

2. The method for forming the semiconductor structure as claimed in claim 1, wherein forming the contact opening through the first interlayer dielectric layer, the contact etching stop layer and the first source/drain feature comprises:
etching the first interlayer dielectric layer to form an opening exposing a top surface of the first source/drain feature;
forming a contact liner along sidewalls of the opening; and
after forming the contact liner, etching the first source/drain feature to extend the opening into the first source/drain feature thereby forming the contact opening.

3. The method for forming the semiconductor structure as claimed in claim 1, wherein a bottom surface of the contact opening is lower than a bottom surface of a topmost one of the nanostructures.

4. The method for forming the semiconductor structure as claimed in claim 1, further comprising:
forming a silicide layer on a surface of the first source/drain feature exposed from the contact opening; and
forming a contact structure on the silicide layer in the contact opening.

5. The method for forming the semiconductor structure as claimed in claim 4, wherein the silicide layer has a V-shape or U-shape.

6. The method for forming the semiconductor structure as claimed in claim 5, further comprising:
forming a dummy gate structure across a channel region of the first active region;
forming a gate spacer layer alongside the dummy gate structure; and
replacing the dummy gate structure with the gate stack, wherein a first nanostructure in the nanostructures includes:
a center portion surrounded by the gate stack; and
an end portion directly under the gate spacer layer and adjacent to the first source/drain feature, wherein in a third direction that is different than the first direction and the second direction, a dimension of the center portion of the first nanostructure is less than a dimension of the end portion of the first nanostructure.

7. The method for forming the semiconductor structure as claimed in claim 1, further comprising:
forming a second interlayer dielectric layer on the gate stack and the first interlayer dielectric layer, wherein the contact opening is further formed through the second interlayer dielectric layer;
forming a metal material to fill the contact opening; and
removing the second interlayer dielectric layer and a portion of the metal material over the first interlayer dielectric layer until the gate stack is exposed.

8. The method for forming the semiconductor structure as claimed in claim 1, further comprising:
forming a second active region adjacent to the first active region, wherein the first active region is formed in an n-type well, and the second active region is formed in a p-type well; and
forming a second source/drain feature on the second active region, wherein:
the first interlayer dielectric layer covers the second source/drain feature, and
the contact opening further penetrates through the second source/drain feature.

9. A method for forming a semiconductor structure, comprising:
forming a transistor in a cell region of a substrate, wherein the transistor includes first, second and third channel layers sequentially stacked over a fin element, a source/drain feature on the fin element, a dielectric layer over the source/drain feature, and a gate stack surrounding the first, second and third channel layers, wherein the third channel layer is thicker than the first channel layer and the second channel layer;
etching the dielectric layer to form an opening exposing the source/drain feature;
extending the opening into the source/drain feature such that a bottom of the opening is lower than a bottom surface of the third channel layer; and
forming a contact structure in the opening, wherein an electrical conductivity of the contact structure is greater than an electrical conductivity of the source/drain feature.

10. The method for forming the semiconductor structure as claimed in claim 9, further comprising:
forming a gate-cut structure through the gate stack, wherein the fin element and the gate-cut structure extend lengthwise along a first direction, and the gate stack extends lengthwise along a second direction that is different than the first direction, and the opening exposes the gate-cut structure.

11. The method for forming the semiconductor structure as claimed in claim 9, wherein the transistor further includes a gate spacer layer between the gate stack and the dielectric layer, and the opening exposes the gate spacer layer.

12. The method for forming the semiconductor structure as claimed in claim 11, further comprising:
forming a contact liner on a sidewall of the gate spacer layer exposed from the opening before extending the opening into the source/drain feature.

13. The method for forming the semiconductor structure as claimed in claim 12, further composing:
forming first, second and third dummy gate structures across an active region, wherein the second dummy gate structure is between the first and third dummy gate structures, and the active region includes the fin element and the first, second and third channel layers; and
replacing the first and third dummy gate structures with first and second fin-cut structures, wherein the first and second fin-cut structures extend into the fin element; and
replacing the second dummy gate structure with the gate stack.

14. The method for forming the semiconductor structure as claimed in claim 9, further comprising:
forming a via on the contact structure; and
forming a power rail on the via, wherein in a top view, the via is located outside an area of the fin element.

15. A semiconductor structure, comprising:
a plurality of nanostructures including a first nanostructure, a second nanostructure and a third nanostructure sequentially stacked upwardly, wherein the third nanostructure is thicker than the second nanostructure and the first nanostructure;
a gate stack extending lengthwise along a first direction and wrapping around center portions of the nanostructures;
a source/drain feature interfaced with end portions of nanostructures, wherein a thickness of the source/drain feature is different from a width of the source/drain feature in a cross-sectional view;
a dielectric layer over the source/drain feature; and
a contact structure through the dielectric layer and the source/drain feature, wherein a bottom surface of the contact structure is lower than a top surface of the second nanostructure.

16. The semiconductor structure as claimed in claim 15, further comprising:
a contact liner between an upper portion of the contact structure and the dielectric layer; and
a silicide layer between a lower portion of the contact structure and the source/drain feature,
wherein a first sidewall of the upper portion of the contact structure is connected to a second sidewall of the lower portion of the contact structure through a connecting wall, and
the second sidewall is offset from the first sidewall by a distance.

17. The semiconductor structure as claimed in claim 15, wherein a slope of the second sidewall is different than a slope of the first sidewall.

18. The semiconductor structure as claimed in claim 15, wherein a top surface of the gate stack is substantially level with a top surface of the contact structure.

19. The semiconductor structure as claimed in claim 15, further comprising:
a fin element under the nanostructures and the source/drain feature, wherein the fin element extends lengthwise along a second direction that is different than the first direction; and
a dielectric separation layer between the fin element and the source/drain feature.

20. The semiconductor structure as claimed in claim 15, wherein a dimension of the center portion of the third nanostructure in the first direction is less than a dimension of the end portion of the third nanostructure in the first direction.
